(19) United States
(12) Patent Application Publication
(10) Pub. No.: US 2024/0222146 A1
(43) Pub. Date: Jul. 4, 2024

(54) RELEASE FILM FOR SEMICONDUCTOR PACKAGE, MANUFACTURING METHOD THEREOF, AND MANUFACTURING METHOD OF SEMICONDUCTOR PACKAGE USING THE SAME

(71) Applicant: SILTECH CO., LTD., Gyeonggi-do (KR)

(72) Inventors: Goan-Hee Yoon, Gyeonggi-do (KR); Jeong-Eun Lee, Gyeonggi-do (KR)

(21) Appl. No.: 17/922,445

(22) PCT Filed: Nov. 29, 2021
(86) PCT No.: PCT/KR2021/017699

§ 371 Date: Oct. 31, 2022

(30) Foreign Application Priority Data
May 31, 2021 (KR) 10-2021-0070252
Oct. 30, 2021 (KR) 10-2021-0147520

(51) Int. Cl. H01L 21/56; C08J 7/044; C08K 3/04; C09D 7/61; C09D 165/00

(52) U.S. Cl. CPC H01L 21/566; C08J 7/044; C09D 7/61; C09D 165/00; C08J 2365/00; C08K 3/041; C08K 2201/001

(57) ABSTRACT

Release films for a semiconductor package, manufacturing methods thereof and manufacturing methods of a semiconductor package using the same are disclosed. A release film for a semiconductor package may include an intermediate body layer including a structure in which at least one polyurethane layer and at least one antistatic layer are laminated, a first release layer disposed on a lower surface of the intermediate body layer and having a first fine unevenness for releasability on a lower surface portion, and a second release layer disposed on an upper surface of the intermediate body layer and having a second fine unevenness for releasability on an upper surface portion. The at least one polyurethane layer may include thermosetting polyurethane having a cross-linkage.

### TECHNICAL FIELD

The present invention relates to a semiconductor package manufacturing technology, and more particularly, to a release film for a semiconductor package, a manufacturing method thereof, and a semiconductor package manufacturing method using the same.

### BACKGROUND ART

In the packaging process of a semiconductor device, a molding process is a process of encapsulating a chip and a carrier substrate on which the chip is mounted with a molding material. A mold molding apparatus is used to encapsulate a semiconductor device, and as a molding material, an epoxy molding compound (EMC) in which an inorganic material and various auxiliary materials are added to a mold resin such as an epoxy resin is mainly used. A molding material including the mold resin is injected into a metal mold to form a mold.

In the packaging process, a method of interposing a release film between the mold and the mold resin may be used as a method of releasing the mold and the molded product after curing of the mold material is completed. The release film is supplied into a molding apparatus, is introduced into a mold temperature-controlled to a molding processing temperature, and is closely adhered to the mold by vacuum suction, and a mold resin is filled thereon. Accordingly, the release film may be disposed between the mold and the mold resin. When the mold is opened at a time when the mold resin is cured, the molded product may be peeled off from the release film.

Conventional release films are mainly made of ETFE (ethylene tetrafluoroethylene) resin. The ETFE release film has thermoplasticity and is mainly manufactured by a T-die ejection method using an extruder. Since the ETFE release film has thermoplastic properties, at a high heating temperature required during the EMC molding process, there is a problem that the release film may not withstand the pressure and the edge portion may be ruptured, which may cause contamination of the mold molding apparatus. Therefore, the ETPE release film has a limitation that it is mainly used at a temperature of about 165° C. or less. In addition, when EMC molding is performed using the ETFE release film, since fume-gas generated from EMC has high permeability through the release film, mold contamination due to fume-gas occurs, and as a result, a cycle of frequently cleaning the mold is required. Therefore, there is a problem that productivity is reduced.

In addition, in the case of a conventional release film, dust or foreign substances may adhere to the film due to an electrification phenomenon, which may cause process defects and mold contamination. Furthermore, in the process of peeling the release film from the mold, the semiconductor devices are damaged or destroyed by electric discharge, resulting in product defects.

Previously, the release films for semiconductor packages including inorganic fillers or polymer antistatic materials have been proposed, but in these cases, there is a problem that antistatic properties are lost during a high-temperature packaging process, or the mold is contaminated due to the drop-off of the inorganic fillers. Furthermore, there is a problem that since the release film is stretched by about 2 mm from the edge portion of the substrate during the packaging process, the antistatic properties of the release film may be lost or deteriorated.

As another process in which a release film is used, an underfill process among semiconductor packaging processes is a process for filling a lower portion of a device in a semiconductor package such as a ball grid array (BGA), a chip scale package (CSP), or a flip chip, and the like, by using an insulating resin. The underfill serves to correct the mismatch in the coefficient of thermal expansion (CTE) between the printed circuit board and the semiconductor device, and also may serve to prevent or minimize the effects of physical shock, chemical shock, and moisture. In addition, the underfill may have a function for dissipating heat generated in the semiconductor device, that is, a heat dissipation function. Such an underfill process is one of the important technical elements in semiconductor packaging.

In a general underfill process, there may occur a problem that the resin material for underfill flows out to a surface portion of the mold apparatus (i.e., a mold) to contaminate the mold apparatus. Therefore, after performing the underfill process, in order to perform the next underfill process, it is necessary to perform a cleaning operation on the mold apparatus. This cleaning operation reduces the process efficiency and becomes a factor to reduce the packaging throughput. In addition, when the substrate on which the semiconductor device is mounted is loaded onto a high-temperature mold apparatus, there is a problem that the substrate is deformed to be convex downwardly (that is, into a U-shape) due to a difference in coefficient of thermal expansion (CTE) between the substrate and the semiconductor device. As a result of it, the workability is deteriorated. Accordingly, there is a need to develop a technology capable of overcoming the problems of the conventional underfill process.

### DISCLOSURE OF THE INVENTION

### Technical Problem

The technical object to be achieved by the present invention is to provide a release film for semiconductor package which has excellent mechanical properties which may withstand high temperature and high pressure conditions without rupture during the molding process of a semiconductor package, and has also excellent mold release properties, and may maintain excellent antistatic performance even during high temperature processing.

In addition, another technical object of the present invention is to provide a release film for a semiconductor package capable of maintaining excellent antistatic properties even when a part of the release film is stretched during the molding process of the semiconductor package.

Another technical object to be achieved by the present invention is to provide a method for forming an underfill capable of significantly improving process efficiency by preventing a problem of contamination of a mold apparatus (i.e., a mold) during an underfill process, and a method for manufacturing a semiconductor package using the same.

In addition, another technical object to be achieved by the present invention is to provide an underfill forming method which may solve the problem of deterioration in workability due to substrate deformation on a mold apparatus (i.e., a mold) during the underfill process, and a method of manufacturing a semiconductor package to which the same is applied.

In addition, the technical object to be achieved by the present invention is to provide a method of manufacturing the above-described release film for a semiconductor package.

The problem to be solved by the present invention is not limited to the above-mentioned problems, and other problems not mentioned will be understood by those skilled in the art from the following description.

### Technical Solution

According to an embodiment of the present invention, there is provided a release film for a semiconductor package, comprising: an intermediate body layer including a structure in which at least one polyurethane layer and at least one antistatic layer are laminated; a first release layer disposed on a lower surface of the intermediate body layer and having a first fine unevenness for releasability on a lower surface portion; and a second release layer disposed on an upper surface of the intermediate body layer and having second a fine unevenness for releasability on an upper surface portion, and wherein the at least one polyurethane layer includes thermosetting polyurethane having a cross-linkage.

The antistatic layer may include a carbon nanotube (CNT). A content of the CNT in the antistatic layer may be about 30˜90 wt %. The CNT may include a multi-walled CNT (MWCNT).

The intermediate body layer may include an intermediate polyurethane layer, a first antistatic layer disposed on a lower surface of the intermediate polyurethane layer, and a second antistatic layer disposed on an upper surface of the intermediate polyurethane layer, and the intermediate polyurethane layer may correspond to the polyurethane layer, and the first and second antistatic layers may correspond to the antistatic layer.

The intermediate body layer may include a first polyurethane layer, a second polyurethane layer and an intermediate antistatic layer disposed between the first and second polyurethane layers, and the first and second polyurethane layers may correspond to the polyurethane layer, and the intermediate antistatic layer may correspond to the antistatic layer.

The polyurethane layer may have a thickness in a range of about 10 μm to 70 μm. The antistatic layer may have a thickness in a range of about 0.1 μm to 2 μm. The release film may have a thickness in a range of about 30 μm to 140 μm.

At least one of the first and second release layers may have the same material composition as that of the polyurethane layer. At least one of the first and second release layers may have a material composition different from that of the polyurethane layer.

At least one of the first and second release layers may include an inorganic material. When the first release layer includes the inorganic material, the first fine unevenness may be formed on the lower surface portion of the first release layer by the inorganic material. When the second release layer includes the inorganic material, the second fine unevenness may be formed on the upper surface portion of the second release layer by the inorganic material.

According to another embodiment of the present invention, there is provided a manufacturing method of a release film for a semiconductor package, the method comprising: preparing a polyurethane layer including thermosetting polyurethane having a cross-linkage; forming a first release layer on any one of a lower surface and an upper surface of the polyurethane layer, and wherein the first release layer is formed while a first antistatic layer is being interposed between the polyurethane layer and the first release layer; and forming a second release layer on the other one of the lower surface and the upper surface of the polyurethane layer, and wherein the second release layer is formed while a second antistatic layer is being interposed between the polyurethane layer and the second release layer and wherein the first release layer has a first fine unevenness for releasability on an opposite surface to a surface in contact with the first antistatic layer, and the second release layer has a second fine unevenness for releasability on an opposite surface to a surface in contact with the second antistatic layer.

The first and second antistatic layers may be formed by a coating method by sing an antistatic coating solution. The antistatic coating solution may contain about 0.1 wt % to about 2 wt % of carbon nanotube (CNT). The first and second antistatic layers may be formed by using a micro-gravure coater or a direct gravure coater.

At least one of the first and second release layers may have the same material composition as that of the polyurethane layer. At least one of the first and second release layers may have a material composition different from that of the polyurethane layer.

According to another embodiment of the present invention, there is provided a manufacturing method of a release film for a semiconductor package, the method comprising: preparing first and second polyurethane layers including thermosetting polyurethane having a cross-linkage; and mutually bonding one surface of the first polyurethane layer and one surface of the second polyurethane layer and wherein the first and second polyurethane layers are mutually bonded while an antistatic layer is being interposed between the first and second polyurethane layers; and wherein a first release layer is provided on the other surface of the first polyurethane layer, a second release layer is provided on the other surface of the second polyurethane layer, the first release layer has a first fine unevenness for releasability on an opposite surface to a surface in contact with the first polyurethane layer, and the second release layer has a second fine unevenness for releasability on an opposite surface to a surface in contact with the second polyurethane layer.

The antistatic layer may be formed by a coating method by using an antistatic coating solution. The antistatic coating solution may contain about 0.1 wt % to about 2 wt % of carbon nanotube (CNT). The antistatic layer may be formed using a micro-gravure coater or a direct gravure coater.

At least one of the first and second release layers may have the same material composition as that of the first and second polyurethane layers. At least one of the first and second release layers may have a material composition different from that of the first and second polyurethane layers.

According to another embodiment of the present invention, there is provided a method for forming an underfill, comprising: preparing a device structure including a circuit board having at least one vent hole, a plurality of semiconductor device portions mounted on the circuit board, and a plurality of electrical connection members disposed between the circuit board and the plurality of semiconductor device portions; disposing a first release film on a first mold member having a plurality of suction holes; disposing the device structure on the first release film, such that the circuit board faces the first release film; forming a plurality of ventilation holes at positions of the first release film corresponding to the plurality of suction holes by applying a first suction pressure to the plurality of suction holes; and filling an underfill material between and around the plurality of electrical connection members while sucking gas above the first release film through the plurality of suction holes and the plurality of ventilation holes by applying a second suction pressure to the plurality of suction holes.

The first release film may be a thermosetting polymer film. The first release film may be a thermosetting polyurethane-based polymer film. The first release film may have a thickness in a range of about 15 μm to 60 μm. The first suction pressure may be in a range of about 20 KPa to 90 KPa.

In the forming of the plurality of ventilation holes, a temperature of the first mold member may be in a range of about 50° C. to 250° C. The plurality of ventilation holes may have a diameter in the range of about 0.05 mm to about 8 mm.

The first mold member may include a first support pin portion disposed on a first edge region and a second support pin portion disposed on a second edge region, the first release film may include a first through hole formed at a position corresponding to the first support pin portion, and a second through hole formed at a position corresponding to the second support pin portion, and, in the disposing of the first release film on the first mold member, the first support pin portion may be inserted into the first through hole, and the second support pin portion may be inserted into the second through hole.

In the filling the underfill material, a portion of the underfill material may pass through the vent hole of the circuit board and contact an upper surface of the first release film.

Before the filling the underfill material, a second mold member facing the first mold member may be disposed on the device structure. The second mold member may be disposed while a second release film is being interposed between the second mold member and the device structure. After the disposing the second mold member, the filling the underfill material may be performed through a molded underfill (MUF) process.

According to another embodiment of the present invention, there is provided a method of manufacturing a semiconductor package, comprising: preparing a device structure including a circuit board having at least one vent hole, a plurality of semiconductor device portions mounted on the circuit board, and a plurality of electrical connection members disposed between the circuit board and the plurality of semiconductor device portions; disposing a first release film on a first mold member having a plurality of suction holes; disposing the device structure on the first release film, such that the circuit board faces the first release film; forming a plurality of ventilation holes at positions of the first release film corresponding to the plurality of suction holes by applying a first suction pressure to the plurality of suction holes; filling an underfill material between and around the plurality of electrical connection members while sucking gas above the first release film through the plurality of suction holes and the plurality of ventilation holes by applying a second suction pressure to the plurality of suction holes; separating the device structure on which the underfill material is formed from the first mold member and the first release film; and dividing the device structure into a plurality of unit devices.

The first release film may be a thermosetting polymer film. The first release film may be a thermosetting polyurethane-based polymer film. The first release film may have a thickness in a range of about 15 μm to 60 μm. The first suction pressure may be in a range of about 20 KPa to 90 KPa. In the forming the plurality of ventilation holes, a temperature of the first mold member may be in a range of about 50° C. to 250° C. The plurality of ventilation holes may have a diameter in a range of about 0.05 mm to about 8 mm.

The first mold member may include a first support pin portion disposed on a first edge region and a second support pin portion disposed on a second edge region, and the first release film may include a first through hole formed at a position corresponding to the first support pin portion, and a second through hole formed at a position corresponding to the second support pin portion. In the disposing of the first release film on the first mold member, the first support pin portion may be inserted into the first through hole, and the second support pin portion may be inserted into the second through hole.

In the filling the underfill material, a portion of the underfill material may pass through the vent hole of the circuit board and contact an upper surface of the first release film.

Before the filling the underfill material, a second mold member facing the first mold member may be disposed on the device structure. The second mold member may be disposed while a second release film is being interposed between the second mold member and the device structure. After the disposing the second mold member, the filling the underfill material may be performed through a molded underfill (MUF) process.

According to embodiments of the present invention, it is possible to implement a release film for a semiconductor package which has remarkable releasability as well as excellent mechanical properties which may withstand high temperature and high pressure conditions without rupture during a molding process of a semiconductor package, and may maintain excellent antistatic performance even during high temperature processing. In addition, according to embodiments of the present invention, it is possible to implement a release film for a semiconductor package capable of maintaining excellent antistatic properties even when a part of the release film is stretched during the molding process of the semiconductor package. When the release film for a semiconductor package according to the embodiment is used, the defect rate of the semiconductor package may be lowered, productivity may be improved, and characteristics of the manufactured package may be improved.

In addition, according to embodiments of the present invention, process efficiency may be greatly improved by preventing a problem of contamination of a mold device (i.e., a mold) in an underfill process during a semiconductor package manufacturing process. In addition, according to embodiments of the present invention, it is possible to effectively solve the problem of deterioration of workability due to deformation of a substrate on the mold device (i.e., the mold) in the underfill process during the manufacturing process of the semiconductor package.

### BRIEF DESCRIPTION OF THE DRAWINGS

FIG. 1 is a cross-sectional diagram illustrating a release film for a semiconductor package according to an embodiment of the present invention.

FIG. 2 is a cross-sectional diagram illustrating a release film for a semiconductor package according to another embodiment of the present invention.

FIG. 3A to FIG. 3C are cross-sectional diagrams illustrating a method of manufacturing a release film for a semiconductor package according to an embodiment of the present invention.

FIG. 4A and FIG. 4B are cross-sectional diagrams illustrating a method for manufacturing a release film for a semiconductor package according to another embodiment of the present invention.

FIG. 5A to FIG. 5D are cross-sectional diagrams illustrating a method for manufacturing a release film for a semiconductor package according to another embodiment of the present invention.

FIG. 6A to FIG. 6C are cross-sectional diagrams illustrating a method of manufacturing a release film for a semiconductor package according to another embodiment of the present invention.

FIG. 7 is a diagram for explaining an apparatus applicable to a method of manufacturing a release film for a semiconductor package according to an embodiment of the present invention and a manufacturing process using the same.

FIG. 8 is a diagram for explaining a molding process of a semiconductor package to which a release film for a semiconductor package is applied according to an embodiment of the present invention.

FIG. 9A to FIG. 9C are cross-sectional diagrams illustrating a method for forming an underfill according to an exemplary embodiment of the present invention.

FIG. 10 is a cross-sectional diagram for explaining a problem of a method for forming an underfill according to a comparative example.

FIG. 11 is a cross-sectional diagram for explaining a problem of an underfill forming method according to a comparative example.

FIG. 12 is a schematic diagram for explaining a process of forming a ventilation hole in a release film in a method for forming an underfill according to an embodiment of the present invention.

FIG. 13 is a schematic diagram for explaining a process of forming a ventilation hole in a release film in an underfill forming method according to a comparative example.

FIG. 14A to FIG. 14D are cross-sectional diagrams for explaining a method for forming an underfill according to another embodiment of the present invention.

FIG. 15A and FIG. 15B are plan diagrams illustrating a process for dividing an underfilled device structure into a plurality of unit devices according to an embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those having common knowledge in the related art, and the scope of the present invention is not limited by the following embodiments. The following embodiment may be modified in many different forms.

The terminology used herein is used to describe specific embodiments, and is not used to limit the present invention. As used herein, terms in the singular form may include the plural form unless the context clearly dictates otherwise. Also, as used herein, the terms “comprise” and/or “comprising” specifies presence of the stated shape, step, number, action, member, element and/or group thereof; and does not exclude presence or addition of one or more other shapes, steps, numbers, actions, members, elements, and/or groups thereof. In addition, the term “connection” as used herein is a concept that includes not only that certain members are directly connected, but also a concept that other members are Furthermore interposed between the members to be indirectly connected.

In addition, in the present specification, when a member is said to be located “on” another member, this includes not only a case in which a member is in contact with another member but also a case in which another member is present between the two members. As used herein, the term “and/or” includes any one and any combination of one or more of those listed items. In addition, as used herein, terms such as “about”, “substantially”, etc. are used as a range of the numerical value or degree, in consideration of inherent manufacturing and material tolerances, or as a meaning close to the range. Furthermore, accurate or absolute numbers provided to aid the understanding of the present application are used to prevent an infringer from using the disclosed present invention unfairly.

Hereinafter, the embodiments of the present invention will be described in detail with reference to the accompanying drawings. The size or the thickness of the regions or the parts illustrated in the accompanying drawings may be slightly exaggerated for clarity and convenience of description. The same reference numerals refer to the same elements throughout the detailed description.

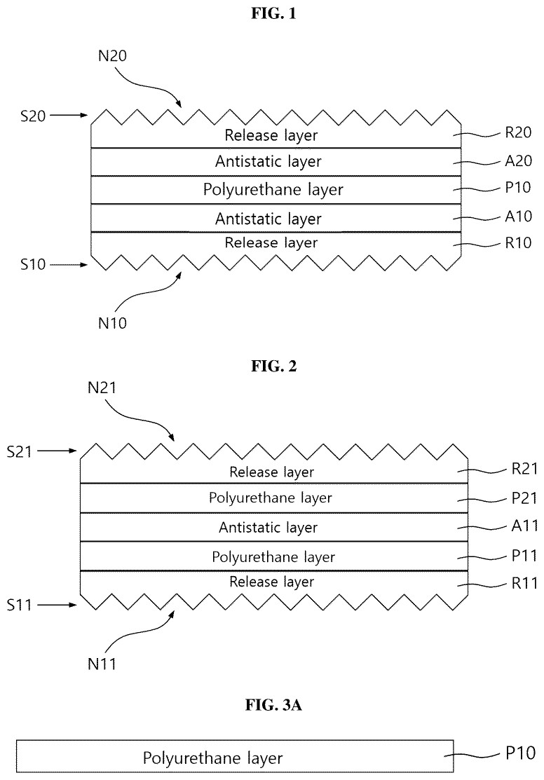

FIG. 1 is a cross-sectional diagram illustrating a release film for a semiconductor package according to an embodiment of the present invention.

Referring to FIG. 1, the release film for a semiconductor package according to this embodiment may include a polyurethane layer (an intermediate polyurethane layer) P10, a first antistatic layer A10 disposed on a lower surface of the polyurethane layer P10, and a second antistatic layer A20 disposed on an upper surface of the polyurethane layer P10. In addition, the release film may include a first release layer R10 disposed on a lower surface of the first antistatic layer A10, and a second release layer R20 disposed on an upper surface of the second antistatic layer A20. The first release layer R10 may have a first fine unevenness N10 for releasability on its lower surface (a lower surface portion), that is, a first surface S10. The second release layer R20 may have a second fine unevenness N20 for releasability on its upper surface (an upper surface portion), that is, a second surface S20. The release film may be said to include an ‘intermediate body layer’ having a structure in which at least one polyurethane layer P10 and at least one antistatic layer A10, A20 are laminated, and it may be said that the first release layer R10 is disposed on a lower surface of the intermediate body layer, and the second release layer R20 is disposed on an upper surface of the intermediate body layer.

The polyurethane layer P10 may include thermosetting polyurethane having a cross-linking bond (cross-linkage). A content of the thermosetting polyurethane in the polyurethane layer P10 may be about 80 wt % or more or about 100 wt %, preferably 80 wt % or more, or about 90 wt % or more. The polyurethane layer P10 may include a thermosetting polyurethane resin as a main constituent material.

In terms of components, the polyurethane resin may have a number average molecular weight (or a weight average molecular weight) of about 50,000 to 500,000. Urethane (polyurethane) may be obtained by reaction of polyol and isocyanate, and may be manufactured by controlling the reaction rate and molecular weight using a catalyst.

As the polyol, one or a mixture of two or more products having a molecular weight of about 500 to 7000 may be used as a raw material. As the ether-based polyol, polypropylene glycol, modified polypropylene glycol, and polytetramethylene glycol (PTMG) may be used. As the polyester-based polyol, polyethylene glycol having a molecular weight in the range of about 500 to 7000, adipate-based polyester polyol which is a polycarbonate-based polycondensation system, and ring-opening polymerization-based lactone-based polyol may be used. One or more of polybutadiene glycol and acryl-based polyol may be mixed and used. However, the above materials are exemplary, and the embodiment of the present invention is not limited thereto.

As the isocyanate material, various diisocyanate-based materials may be used. For example, PPDI may be used as p-phenylene diisocyanate with a molecular weight of 160.1. TDI including isomer of toluene-diisocyanate may be used as toluene-diisocyanate with a molecular weight of 174.2, NDI may be used as 1,5-naphthalene diisocyanate with a molecular weight of 210.2, HDI may be used as 1,6-hexamethylene diisocyanate with a molecular weight of 168.2. MDI may be used as 4,4′-diphenylmethane diisocyanate with a molecular weight of 250.3. IPDI may be used as isoporon diisocyanate with a molecular weight of 222.3, and H12MDI may be used as cyclohexylmethane diisocyanate with a molecular weight of 262. However, the above materials are exemplary, and the present application is not limited thereto.

In addition, a chain extender material may be additionally used in addition to the polyol and isocyanate. The chain extender may serve to increase the molecular weight of the polyurethane and impart various functionalities. One to two or more of the chain extenders may be mixed and used. As the chain extender, ethylene glycol-based material, propylene glycol-based material, butadiene glycol-based material, polyhydric alcohol including silicone, polyhydric alcohol including fluorine, etc. may be used. However, the above materials are exemplary, and the present application is not limited thereto.

As the catalyst, various organic tin-based materials and organic bismuth-based materials may be used. The organotin-based material (an organotin-based compound) may include, for example, dibutyltin dilaurate, stannous octoate, dibutyltin diacetate, dibutyltin dimercaptide, and the like. Here, dibutyltin dilaurate is (CH₃CH₂CH₂CH₂)₂Sn[CH₃(CH₂)₁₀COO]₂, stannous octoate is Sn[C₇H₁₅COO]₂, dibutyltin diacetate is (CH₃CH₂CH₂CH₂)₂Sn[CH₃COO]₂, dibutyltin dimercaptide is (CH₃CH₂CH₂CH₂)₂Sn[SC₁₂H₂₅]. The organic bismuth-based material (an organic bismuth-based compound) may have various molecular weights, and may include, for example, a carboxylate-based catalyst material containing bismuth. Here, the carboxylate-based catalyst material may contain about 9% to about 45% of bismuth. However, the above materials are exemplary, and the present application is not limited thereto.

As a solvent for preparing a polyurethane resin solution, for example, various acetone solvents including DMF (dimethylformamide), DEF (diethylformamide), DMSO (dimethylsulfoxaide), DMAC (dimethylacetamide), toluene, ethyl acetate (EA), methyl ethyl ketone, and the like may be used. However, the above materials are exemplary, and the present application is not limited thereto.

After preparing a resin solution for preparing polyurethane in which the polyol, isocyanate, solvent, etc. are mixed, a polymer cured product having various crosslinking densities may be formed by a reaction using a melamine-based curing agent, its catalyst, and an isocyanate-based curing agent polymerized with various molecular weights. In this case, a curing method using heat may be applied.

In the polyurethane composition, as a first material for the urethane reaction, a polyol such as a polyester-based polyol (e.g., molecular weight 500 to 7000), polyether-based polyol (e.g., molecular weight 200 to 3000) or polycarbonate-based polyol (e.g., molecular weight 500 to 8000) may be applied, and an isocyanate-based material may be applied as a second material for the urethane reaction. As the isocyanate-based material, various isocyanate types containing a yellowing benzene-ring, and various isocyanates including hexamethylene-based, isophorone-based and cyclohexylmethane-based which are non-yellowing types may be used. In addition, a chain extender may be additionally used to increase the molecular weight of the polyurethane. As the chain extender, ethylene glycol-based materials, propylene glycol-based materials, butadiene glycol-based materials, polyhydric alcohols including silicone, polyhydric alcohols including fluorine, etc. may be used, and it is possible to increase the molecular weight of the polyurethane by involving the chain extender in a urethane reaction.

In some cases, the polyurethane layer P10 may contain some (small amount) of other polymer materials or other additives other than the thermosetting polyurethane, for example, an initiator (activator) for crosslinking reaction, a leveling agent and/or an antifoaming agent. As the leveling agent, a modified polyether-based leveling agent including a silicone-based, fluorine-based or non-silicone-based leveling agent may be used, and the leveling agent may be used in a mixture of about 0.1 wt % to 5 wt %. The antifoaming agent is for a defoaming function and for example, a silicone-based or non-silicone-based antifoaming agent may be used. The antifoaming agent may be used in a mixture of about 0.1 wt % to 5 wt %. In addition, as a curing agent for the curing reaction of the prepared polyurethane, a melamine-based curing agent, and an isocyanate-based curing agent polymerized with several molecules may be used. In addition, the curing reaction may be accelerated in the presence of an acid catalyst.

The first and second antistatic layers A10 and A20 may include carbon nanotube (CNT) as an antistatic material. Antistatic properties may be exhibited due to the conductive properties of the CNTs. A plurality (a large amount) of CNTs may be contained in each of the first and second antistatic layers A10 and A20. A plurality of CNTs in each of the first and second antistatic layers A10 and A20 may at least partially form a network structure. The content of the CNTs in each of the first and second antistatic layers A10 and A20 may be about 30 wt % to about 90 wt %. In addition, the CNT may be a multi-walled CNT (MWCNT). When these conditions are satisfied, the first and second antistatic layers A10 and A20 may be advantageous in exhibiting excellent antistatic performance even at a high elongation (or referred to as elongation) of the release film. Even if the release film is stretched to some extent, the plurality of CNTs may maintain a network structure, and antistatic performance may be maintained. The first and second antistatic layers A10 and A20 may also be referred to as ‘electrostatic prevention layers’, ‘antistatic sheets’ or ‘antistatic coating layers’.

Each of the first and second antistatic layers A10 and A20 may further include a predetermined polymer material serving as an adhesive. The polymer material may include, for example, silicone. The silicone may be, for example, hybrid silicone. In addition, each of the first and second antistatic layers A10 and A20 may further include a conductive polymer material. The conductive polymer material secures a conductive path between CNT particles, and secures conductivity together with flexibility. As a non-limiting example, the conductive polymer material may be PEDOT:PSS [poly(3,4-ethylenedioxythiophene): poly(styrenesulfonate)]. The antistatic performance may be further improved by using a polymer conductor material such as PEDOT:PSS and CNT together. When the silicone is applied to the antistatic layers A10 and A20, a content thereof may be about 5 to 30 wt %. When the conductive polymer material is applied to the antistatic layers A10 and A20, a content thereof may be about 5 to 65 wt %.

The first release layer R10 may have a first surface S10 on an opposite side of the first antistatic layer A10, and the first surface S10 may include the first fine unevenness N10 at least for improving the releasability. In the drawing, the lower surface of the first release layer R10 may be the first surface S10, and the first antistatic layer A10 may be bonded to the upper surface of the first release layer R10. The second release layer R20 may have a second surface S20 on an opposite side of the second antistatic layer S20, and the second surface S20 may include the second fine unevenness N20 at least for improving the releasability. In the drawing, the upper surface of the second release layer R20 may be the second surface S20, and the second antistatic layer A20 may be bonded to the lower surface of the second release layer R20.

The first surface S10 may have a surface roughness Ra of about 5 μm or more due to the first fine unevenness N10. In an embodiment, the surface roughness Ra of the first surface S10 may be about 5 μm to about 20 μm. The second surface S20 may have a surface roughness Ra of about 5 μm or more due to the second fine unevenness N20. In an embodiment, the surface roughness Ra of the second surface S20 may be about 5 μm to about 20 μm. However, the surface roughness Ra of the first surface S10 and the second surface S20 is not limited to the above-mentioned levels, and may be designed differently in some cases.

At least one of the first and second release layers R10 and R20 may have the same material composition as that of the polyurethane layer P10. In this case, at least one of the first and second release layers R10 and R20 may include thermosetting polyurethane having a cross-linkage bond. In this case, the content of the thermosetting polyurethane in at least one of the first and second release layers R10 and R20 may be about 80 wt % or more or about 90 wt % or more. According to an embodiment, the content of the thermosetting polyurethane in at least one of the first and second release layers R10 and R20 may be about 80 wt % to 100 wt %.

However, at least one of the first and second release layers R10 and R20 may have a material composition different from that of the polyurethane layer P10. In this case, at least one of the first and second release layers R10 and R20 may further include an inorganic material. When the first release layer R10 includes the inorganic material, the first fine unevenness N10 may be formed on the lower surface of the first release layer R10, that is, the first surface S10 by the inorganic material. When the second release layer R20 includes the inorganic material, the second fine unevenness N20 may be formed on the upper surface of the second release layer R20, that is, the second surface S20 by the inorganic material.

More specifically, the first release layer R10 may include a base layer portion made of thermosetting polyurethane, and an inorganic material contained in the base layer portion, and the first fine unevenness N10 may be formed by the inorganic material. The inorganic material may, for example, have a form of particle (a plurality of particles). In addition, the inorganic material may include, for example, at least one of silica, calcium carbonate (CaCO₃), and barium sulfate (BaSO₄). However, the type of inorganic material which may be used in the embodiment of the present invention is not limited to the above-mentioned descriptions, and may be variously changed. When the first release layer R10 includes the inorganic material, the inorganic material may be referred to as a kind of filler. In this case, the content of the thermosetting polyurethane with respect to the total amount of the thermosetting polyurethane and the inorganic material in the first release layer R10 may be about 60 wt % or more or about 80 wt % or more. For example, the content of the thermosetting polyurethane with respect to the total amount of the thermosetting polyurethane and the inorganic material in the first release layer R10 may be about 60 wt % to about 97 wt %. The content of the thermosetting polyurethane in the first release layer R10 in the region other than the inorganic material may be about 80 wt % to 100 wt %. In the remaining region except for the inorganic material, the first release layer R10 may include thermosetting polyurethane as a main constituent material or may be composed of thermosetting polyurethane. In addition, in some cases, the first release layer R10 may include an amount (a small amount) of another polymer material or other additives (e.g., a leveling agent, an antifoaming agent, etc.) in addition to the thermosetting polyurethane.

Similar to the first release layer R10, the second release layer R20 may include a base layer portion made of thermosetting polyurethane and an inorganic material contained in the base material layer portion, and the second fine unevenness N20 may be formed by the inorganic material. The material and shape of the inorganic material may be the same as described above. When the second release layer R20 includes the inorganic material, the inorganic material may be referred to as a kind of filler. In this case, the content of the thermosetting polyurethane with respect to the total amount of the thermosetting polyurethane and the inorganic material in the second release layer R20 may be about 60 wt % or more or about 80 wt % or more. For example, the content of the thermosetting polyurethane with respect to the total amount of the thermosetting polyurethane and the inorganic material in the second release layer R20 may be about 60 wt % to about 97 wt %. The content of the thermosetting polyurethane in the second release layer R20 in the region other than the inorganic material may be about 80 wt % to 100 wt %. In the remaining region except for the inorganic material, the second release layer R20 may include thermosetting polyurethane as a main constituent material or may be composed of thermosetting polyurethane. In addition, in some cases, the second release layer R20 may include an amount (a small amount) of another polymer material or other additives (e.g., a leveling agent, an antifoaming agent, etc.) in addition to the thermosetting polyurethane.

The release film according to an embodiment of the present invention may have a thickness (a total thickness) in the range of about 30 μm to 140 μm. The thickness of the release film may be, for example, about 50 μm to about 120 μm or about 50 μm to about 100 μm. Under these thickness conditions, the release film may have excellent mechanical properties suitable for a molding process. The thickness of the polyurethane layer P10 may be, for example, about 10 μm to 70 μm, the thickness of the first release layer R10 may be, for example, about 10 μm to 70 μm, and the thickness of the second release layer R20 may be, for example, about 10 μm to 70 μm. The thickness of the first release layer R10 may be the same as or similar to the thickness of the second release layer R20. The thickness of the polyurethane layer P10 may be the same as the thickness of each of the first release layer R10 and the second release layer R20, but may be different. In the latter case, the thickness of the polyurethane layer P10 may be thinner than the thickness of each of the first release layer R10 and the second release layer R20. When the above thickness conditions are satisfied, it may be advantageous for easy formation (manufacturing) and improvement of mechanical properties of the release film.

Meanwhile, each of the first and second antistatic layers A10 and A20 may have a thickness of about 0.1 μm to 2 μm. When these thickness conditions are satisfied, the first and second antistatic layers A10 and A20 may more effectively exhibit antistatic performance in the release film.

FIG. 2 is a cross-sectional diagram illustrating a release film for a semiconductor package according to another embodiment of the present invention.

Referring to FIG. 2, the release film for a semiconductor package according to this embodiment may include a first polyurethane layer P11, a second polyurethane layer P21, and an antistatic layer A11 (an intermediate antistatic layer) disposed therebetween. In addition, the release film may include a first release layer R11 disposed on a lower surface of the first polyurethane layer P11, and a second release layer R21 disposed on an upper surface of the second polyurethane layer P21. The first release layer R11 may have a first fine unevenness N11 for releasability on its lower surface (a lower surface portion), that is, a first surface S11. The second release layer R21 may have a second fine unevenness N21 for releasability on its upper surface (an upper surface portion), that is, a second surface S21. The release film may be said to include an ‘intermediate body layer’ having a structure in which at least one polyurethane layer P11, P21 and at least one antistatic layer A11 are laminated, and it may be said that a first release layer R11 is disposed on a lower surface of the intermediate body layer and a second release layer R21 is disposed on an upper surface of the intermediate body layer.

The first and second polyurethane layers P11 and P21 may include thermosetting polyurethane having a cross-linking bond. A content of the thermosetting polyurethane in the first polyurethane layer P11 may be about 80 wt % or more or about 90 wt % or more. In one embodiment, the content of the thermosetting polyurethane in the first polyurethane layer P11 may be about 80 wt % to 100 wt %. A content of the thermosetting polyurethane in the second polyurethane layer P21 may be about 60 wt % or more or about 80 wt % or more. In one embodiment, the content of the thermosetting polyurethane in the second polyurethane layer P21 may be about 60 wt % to 97 wt %, or about 60 wt % to 100 wt %. Each of the first and second polyurethane layers P11 and P21 may include thermosetting polyurethane as a main constituent material or may be composed of thermosetting polyurethane. In addition, in some cases, at least one of the first and second polyurethane layers P11 and P21 may contain some (a small amount) of other polymer materials or other additives (e.g., leveling agents, antifoaming agents, etc.) in addition to the thermosetting polyurethane. The material composition of each of the first and second polyurethane layers P11 and P21 may be the same as or similar to that of the polyurethane layer P10 of FIG. 1.

The first release layer R11 may have a first surface S11 on an opposite side to the first polyurethane layer P11, and the first surface S11 may include a first fine unevenness N11 at least for improving the releasability. In the drawing, the lower surface of the first release layer R11 may be the first surface S11, and the first polyurethane layer P11 may be bonded to the upper surface of the first release layer R11. The second release layer R21 may have a second surface S22 on an opposite side to the second polyurethane layer P21, and the second surface S22 may include a second fine unevenness N22 at least for improving the releasability. In the drawing, the upper surface of the first release layer R21 may be the second surface S22, and the second polyurethane layer P21 may be bonded to the lower surface of the first release layer R21. The range condition of the surface roughness Ra of each of the first surface S11 and the second surface S22 may be the same as or similar to that described for the first surface S10 and the second surface S20 in FIG. 1.

At least one of the first and second release layers R11 and R21 may have the same material composition as the polyurethane layers P11 and P21. In this case, at least one of the first and second release layers R11 and R21 may include thermosetting polyurethane having a cross-linking bond. In this case, a content of the thermosetting polyurethane in at least one of the first and second release layers R11 and R21 may be about 80 wt % or more or about 90 wt % or more. According to an embodiment, the content of the thermosetting polyurethane in at least one of the first and second release layers R11 and R21 may be about 80 wt % to 100 wt %.

However, at least one of the first and second release layers R11 and R21 may have a material composition different from that of the polyurethane layers P11 and P21. In this case, at least one of the first and second release layers R11 and R21 may further include an inorganic material. When the first release layer R11 includes the inorganic material, the first fine unevenness N11 may be formed on the lower surface of the first release layer R11, that is, the first surface S11 by the inorganic material. When the second release layer R21 includes the inorganic material, the second fine unevenness N21 may be formed on the upper surface, that is, the second surface S21, of the second release layer R21 by the inorganic material.

The first release layer R11 may include a base layer portion made of thermosetting polyurethane and an inorganic material contained in the base layer portion, and the first fine unevenness N11 may be formed by the inorganic material. The inorganic material may, for example, have a particle type (a plurality of particles). In addition, the inorganic material may include, for example, at least one of silica, calcium carbonate (CaCO₃), and barium sulfate (BaSO₄). However, the type of inorganic material which may be used in the embodiment of the present invention is not limited to the above-mentioned types, and may be variously changed. When the first release layer R11 includes the inorganic material, the inorganic material may be referred to as a kind of filler. In this case, the content of the thermosetting polyurethane relative to the total amount of the thermosetting polyurethane and the inorganic material in the first release layer R11 may be about 60 wt % or more or about 80 wt % or more. For example, the content of the thermosetting polyurethane with respect to the total amount of the thermosetting polyurethane and the inorganic material in the first release layer R11 may be about 60 wt % to about 97 wt %. The content of the thermosetting polyurethane in the first release layer R11 in the region other than the inorganic material may be about 80 wt % to 100 wt %. In the remaining region except for the inorganic material, the first release layer R11 may include thermosetting polyurethane as a main constituent material or may be composed of thermosetting polyurethane. Also, in some cases, the first release layer R11 may include an amount (a small amount) of another polymer material or other additives (e.g., a leveling agent, an antifoaming agent, etc.) in addition to the thermosetting polyurethane.

Similar to the first release layer R11, the second release layer R21 may include a base layer portion made of thermosetting polyurethane and an inorganic material contained in the base layer portion, and the second fine unevenness N21 may be formed by the inorganic material. The material and shape of the inorganic material may be the same as described above. When the second release layer R21 includes the inorganic material, the inorganic material may be referred to as a kind of filler. In this case, the content of the thermosetting polyurethane with respect to the total amount of the thermosetting polyurethane and the inorganic material in the second release layer R21 may be about 60 wt % or more or about 80 wt % or more. For example, the content of the thermosetting polyurethane with respect to the total amount of the thermosetting polyurethane and the inorganic material in the second release layer R21 may be about 60 wt % to about 97 wt %. The content of the thermosetting polyurethane in the second release layer R21 in the region other than the inorganic material may be about 80 wt % to 100 wt %. In the region other than the inorganic material, the second release layer R21 may include thermosetting polyurethane as a main constituent material or may be composed of thermosetting polyurethane. In addition, in some cases, the second release layer R21 may include an amount (a small amount) of another polymer material or other additives (e.g., a leveling agent, an antifoaming agent, etc.) in addition to the thermosetting polyurethane.

The antistatic layer A11 may have the same or similar material composition to the first and second antistatic layers A10 and A20 of FIG. 1. That is, the antistatic layer A11 may include a carbon nanotube (CNT) as an antistatic material. A plurality (a large amount) of CNTs may be contained in the antistatic layer A11, and the plurality of CNTs may at least partially form a network structure. The content of the CNT in the antistatic layer A11 may be about 30 wt % to about 90 wt %. In addition, the CNT may be a multi-walled CNT (MWCNT). Such an antistatic layer A11 may maintain excellent antistatic performance even at a high elongation of the release film.

In addition, the antistatic layer A11 may further include a predetermined polymer material serving as an adhesive or the like. The polymer material may include, for example, silicone. The silicone may be, for example, hybrid silicone. In addition, the antistatic layer A11 may further include a polymer conductor material such as PEDOT:PSS. When the silicon is applied to the antistatic layer A11, its content may be about 5 wt % to 30 wt %. When the polymer conductor material such as PEDOT:PSS is applied to the antistatic layer A11, its content may be about 5 wt % to about 65 wt %.

In the embodiment of FIG. 2, the total thickness of the release film and the thickness range of each of the layer portions P11/P21, A112, and R11/R21 may be the same as or similar to those described for the release film of FIG. 1. That is, the release film of FIG. 2 may have a thickness (a total thickness) in the range of about 30 to 140 μm. The thickness of each of the first and second polyurethane layers P11 and P21 may be, for example, about 10 μm to 70 μm, and the thickness of each of the first and second release layers R11 and R21 may be, for example, about 10 μm to about 70 μm, and the thickness of the antistatic layer A11 may be, for example, about 0.1 μm to about 2 μm.

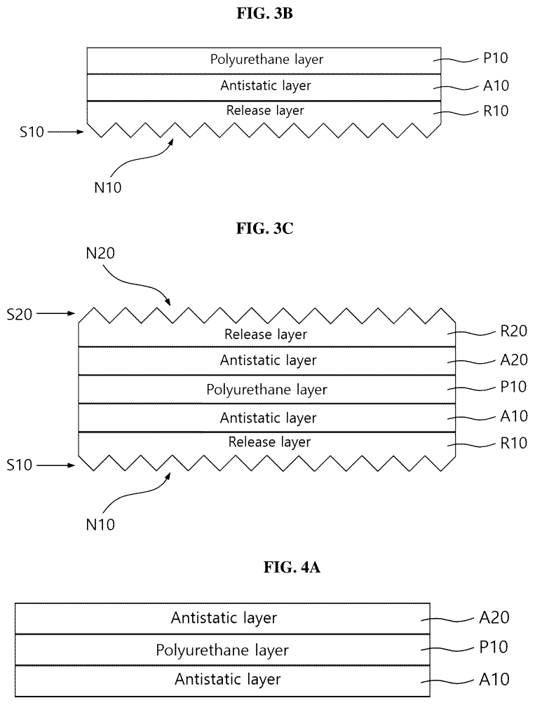

FIG. 3A to FIG. 3C are cross-sectional diagrams illustrating a method of manufacturing a release film for a semiconductor package according to an embodiment of the present invention.

Referring to FIG. 3A, a polyurethane layer P10 including thermosetting polyurethane having a cross-linkage may be prepared. The polyurethane layer P10 may be formed from a solution for forming polyurethane. The solution for forming polyurethane may be applied on a predetermined base layer (not shown) or a carrier film (not shown), and a cured polyurethane layer P10 may be formed from the applied polyurethane forming solution. Accordingly, the polyurethane layer P10 may be disposed on a predetermined base layer (not shown) or a carrier film (not shown). The base layer or the carrier film may be easily peeled off from the polyurethane layer P10.

Although not shown in FIG. 3A, a first release layer (R10 in FIG. 3B) having a first fine unevenness for releasability may be provided on one surface, and a second release layer (R20 in FIG. 3C) having a second fine unevenness for releasability may be provided on one surface.

Referring to FIG. 3B, a first release layer R10 may be formed on any one of the lower surface and the upper surface of the polyurethane layer P10, for example, the lower surface of the drawing. Furthermore, the first release layer R10 may be formed while a first antistatic layer A10 is being interposed between the polyurethane layer P10 and the first release layer R10 therebetween. For example, the first antistatic layer A10 may be formed by a coating method using an antistatic coating solution. That is, the first antistatic layer A10 may be formed by coating the antistatic coating solution on the lower surface of the polyurethane layer P10 or the upper surface of the first release layer R10 and drying or curing the coated antistatic coating solution under the given conditions. Here, the antistatic coating solution may include a carbon nanotube (CNT). At this time, a content of CNT in the antistatic coating solution may be about 0.1 wt % to about 2 wt %. In addition, the antistatic coating solution may further include silicone (e.g., hybrid silicone) which may be used as an adhesive in addition to CNT, PEDOT:PSS which is a polymer conductor, and ethyl alcohol and isopropyl alcohol which are solvents. In this case, a content of the silicone in the antistatic coating solution may be about 0.1 wt % to about 0.5 wt %, a content of PEDOT:PSS may be about 0.1 wt % to about 2 wt %, and a content of ethyl alcohol may be about 20 wt % to about 40 wt %, and a content of the isopropyl alcohol may be about 30 wt % to about 75 wt %. However, use of a polymer conductor such as PEDOT:PSS may be optional, the silicone may be substituted with another polymer, and the type of solvent may be varied.

The first antistatic layer A10 may be formed by a coating method using a micro-gravure coater or a direct gravure coater. When using a micro-gravure coater or a direct gravure coater, it may be advantageous to secure excellent coating properties. However, the type of coating equipment may be changed depending on the case.

The first release layer R10 may be formed on a predetermined base layer (not shown) or a carrier film (not shown). For example, the base layer may be a ‘matte film’. The matte film is a matte-treated film, and the matte treatment in this specification may refer to a matte process for forming a fine unevenness on the surface. The matte film may be, for example, a polyethylene terephthalate (PET) film, but the material of the matte film is not limited thereto and may vary. More specifically, when a polymer-forming solution is applied on the matte-treated surface of the mat film and a cured first release layer R10 is formed therefrom, the first fine unevenness N10 may be formed on the first surface S10 of the first release layer R10 bonded to the matte film. It may be said that the shape of the matte-treated surface of the mat film is transferred to the first surface S10 of the first release layer R10. The polymer-forming solution may include, for example, a urethane-based source material, a solvent, and a curing agent, etc. However, the first release layer R10 may not be formed on the mat film. For example, the first fine unevenness N10 of the first release layer R10 may be formed by an inorganic material included in the first release layer R10.

Referring to FIG. 3C, a second release layer R20 may be formed on the other one of the lower surface and the upper surface of the polyurethane layer P10, for example, on the upper surface in the drawing. Furthermore, the second release layer R20 may be formed with a second antistatic layer A20 interposed between the polyurethane layer P10 and the second release layer R20.

For example, the second antistatic layer A20 may be formed by a coating method using an antistatic coating solution. That is, the second antistatic layer A20 may be formed by coating the antistatic coating solution on the upper surface of the polyurethane layer P10 or the lower surface of the second release layer R20, and drying or curing the coated antistatic coating solution under given conditions. The antistatic coating solution may include CNT. A specific method for forming the second antistatic layer A20 and the composition of the antistatic coating solution may be the same as or similar to those described with respect to the first antistatic layer A10 in FIG. 3B.

The second release layer R20 may be formed on a predetermined base layer (not shown) or a carrier film (not shown). For example, the base layer may be a ‘matte film’. When a polymer-forming solution is applied on the mat-treated surface of the matte film and a cured second release layer R20 is formed therefrom, the second fine unevenness N20 may be formed on the second surface S20 of the second release layer R20 bonded to the matte film. The polymer-forming solution may include, for example, a urethane-based source material, a solvent, and a curing agent, etc. However, the second release layer R20 may not be formed on the matte film. For example, the second fine unevenness N20 of the second release layer R20 may be formed by an inorganic material included in the second release layer R20.

At least one of the first and second release layers R10 and R20 may have the same material composition as that of the polyurethane layer P10. In this case, at least one of the first and second release layers R10 and R20 may include thermosetting polyurethane having a cross-linking bond. However, at least one of the first and second release layers R10 and R20 may have a material composition different from that of the polyurethane layer P10. In this case, at least one of the first and second release layers R10 and R20 may further include an inorganic material. When the first release layer R10 includes the inorganic material, the first fine unevenness N10 may be formed on the lower surface of the first release layer R10, that is, the first surface S10 by the inorganic material. When the second release layer R20 includes the inorganic material, the second fine unevenness N20 may be formed on the upper surface of the second release layer R20, that is, the second surface S20 by the inorganic material. The inorganic material may, for example, have a particle types (a plurality of particles). In addition, the inorganic material may include, for example, at least one of silica, calcium carbonate (CaCO₃) and barium sulfate (BaSO₄). At this time, the solution for forming the polymer used to form the first release layer R10 or the second release layer R20 may be a solution in which the inorganic material is mixed with the solution for forming polyurethane for forming the polyurethane layer P10. When at least one of the first and second release layers R10 and R20 includes the inorganic material, a detailed configuration may be the same as that described in FIG. 1, and thus a repeated description thereof will be omitted.

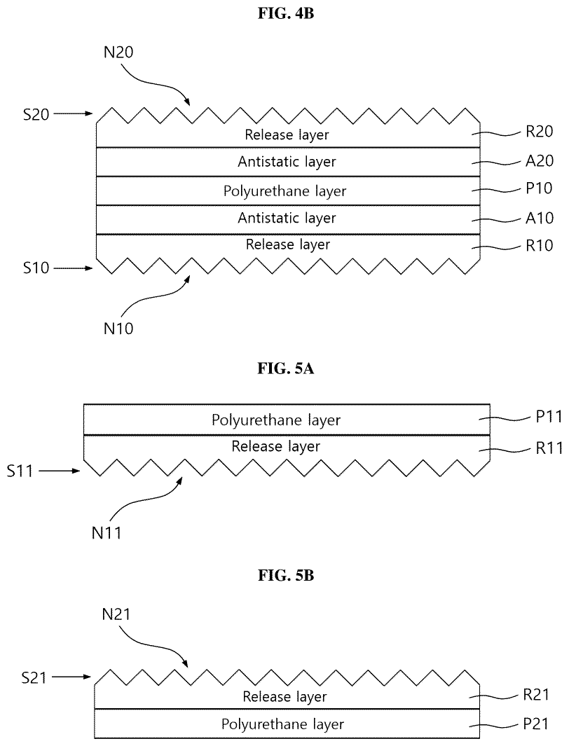

FIG. 4A and FIG. 4B are cross-sectional diagrams illustrating a method for manufacturing a release film for a semiconductor package according to another embodiment of the present invention.

Referring to FIG. 4A, a polyurethane layer P10 including thermosetting polyurethane having a cross-linkage may be prepared. The polyurethane layer P10 may be formed from a solution for forming polyurethane. Then, a first antistatic layer A10 and a second antistatic layer A20 may be formed on lower and upper surfaces of the polyurethane layer P10, respectively. A specific method for forming the first and second antistatic layers A10 and A20 and a material composition thereof may be the same as described above.

Referring to FIG. 4B, a first release layer R10 may be formed on a lower surface of the first antistatic layer A10. In addition, a second release layer R20 may be formed on an upper surface of the second antistatic layer A20. Here, the term ‘formation’ may be a term encompassing the concepts of ‘application’, ‘coating’, ‘bonding’, or ‘lamination’. The terms such as ‘application’, ‘coating’, ‘bonding’, or ‘lamination’ may be used interchangeably and have the same meaning unless specifically used, and the present invention is not limited by these terms. The concept of terms may be applied throughout this specification. The first release layer R10 may have a first fine unevenness N10 for releasability on an opposite surface to a surface in contact with the first antistatic layer A10, that is, on a first surface S10. The second release layer R20 may have a second fine unevenness N20 for releasability on an opposite surface to a surface in contact with the second antistatic layer A20, that is, on a second surface S20.

At least one of the first and second release layers R10 and R20 may have the same material composition as that of the polyurethane layer P10. In this case, at least one of the first and second release layers R10 and R20 may include thermosetting polyurethane having a cross-linking bond. However, at least one of the first and second release layers R10 and R20 may have a material composition different from that of the polyurethane layer P10. In this case, at least one of the first and second release layers R10 and R20 may further include an inorganic material. When at least one of the first and second release layers R10 and R20 includes the inorganic material, a specific configuration may be the same as described above.

Although the method of manufacturing the release film of FIG. 1 has been specifically described in FIGS. 3A to 3C and FIGS. 4A and 4B, this is exemplary and may be variously changed in some cases.

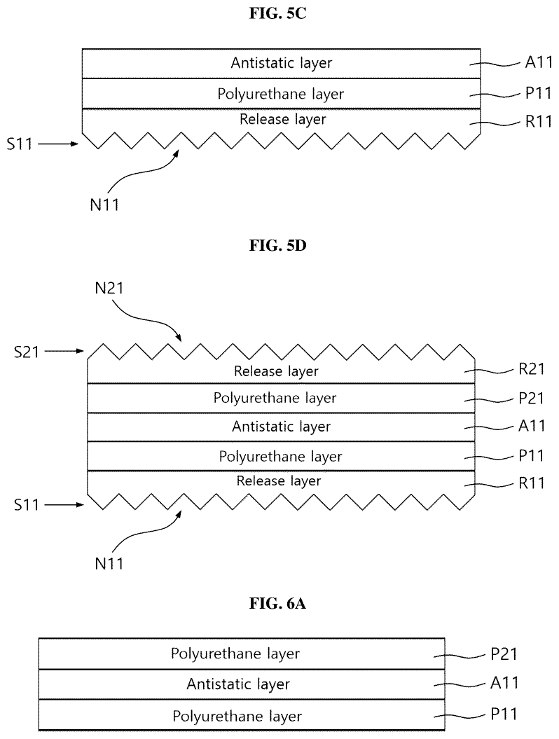

FIG. 5A to FIG. 5D are cross-sectional diagrams illustrating a method for manufacturing a release film for a semiconductor package according to another embodiment of the present invention.

Referring to FIG. 5A, a first release layer R11 and a first polyurethane layer P11 bonded thereto may be prepared. For example, after forming the first release layer R11 on a first mat film (not shown), the first polyurethane layer P11 may be formed by applying a polyurethane-forming solution on one surface of the first release layer R11 and curing it. In some cases, after forming the first polyurethane layer P11 first, the first release layer R11 may be formed on one surface of the first polyurethane layer P11. The first release layer R11 may have the same material composition as the first polyurethane layer P11, but may have a different material composition. In the latter case, the first release layer R11 may include an inorganic material as described above. The first release layer R11 may have a first fine unevenness N11 on an opposite surface to a surface in contact with the first polyurethane layer P11, that is, on a first surface S11.

Referring to FIG. 5B a second release layer R21 and a second polyurethane layer P21 bonded thereto may be prepared. For example, after forming the second release layer R21 on a second matte film (not shown), a polyurethane layer P21 may be formed by applying a polyurethane-forming solution on one surface of the second release layer R21 and curing the applied solution. In some cases, after forming the second polyurethane layer P21 first, the second release layer R21 may be formed on one surface of the second polyurethane layer P21. The second release layer R21 may have the same material composition as the second polyurethane layer P21, but may have a different material composition. In the latter case, the second release layer R21 may include an inorganic material as described above. The second release layer R21 may have a second fine unevenness N21 on an opposite surface to a surface in contact with the second polyurethane layer P21, that is, on a second surface S21.

Referring to FIG. 5C, an antistatic layer A11 may be formed on one surface (an upper surface in the drawing) of the first polyurethane layer P11 described in FIG. 5A. A specific method for forming the antistatic layer A11 may be the same as or similar to that described above.

Referring to FIG. 5D, the first polyurethane layer P11 and the second polyurethane layer P21 described in FIG. 5B may be bonded with the antistatic layer A11 interposed therebetween. As a result, the release film according to the embodiment as described with reference to FIG. 2 may be manufactured.

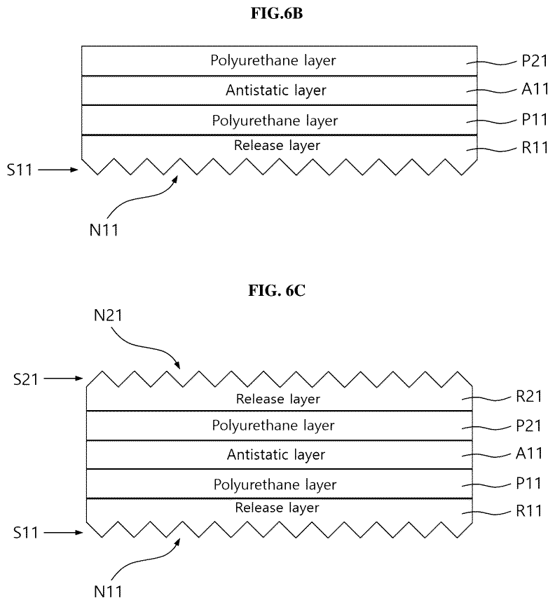

FIG. 6A to FIG. 6C are cross-sectional diagrams illustrating a method of manufacturing a release film for a semiconductor package according to another embodiment of the present invention.

Referring to FIG. 6A, first and second polyurethane layers P11, P21 containing thermosetting polyurethane having a cross-linkage may be prepared, and the first polyurethane layer P11 and the second polyurethane layer P21 may be bonded mutually while one surface of the first polyurethane layer P11 (an upper surface in the drawing) is bonded to one surface (a lower surface in the drawing) of the second polyurethane layer P21, and an antistatic layer A11 is interposed between the first and second polyurethane layers P11, P21. Here, a specific method for forming the antistatic layer A11 may be the same as or similar to that described above.

Referring to FIG. 6B, a first release layer R11 may be formed on the other surface (a lower surface in the drawing) of the first polyurethane layer P11. The first release layer R11 may have a first fine unevenness N11 on an opposite surface to a surface in contact with the first polyurethane layer P11, that is, on a first surface S11. The first release layer R11 may have the same material composition as the first polyurethane layer P11 or may have a different material composition. In the latter case, the first release layer R11 may include the aforementioned inorganic material.

Referring to FIG. 6C, a second release layer R21 may be formed on the other surface (an upper surface in the drawing) of the second polyurethane layer P21. The second release layer R21 may have a second fine unevenness 21 on an opposite surface to a surface in contact with the second polyurethane layer P21, that is, on a second surface S21. The second release layer R21 may have the same material composition as the second polyurethane layer P21 or may have a different material composition. In the latter case, the second release layer R21 may include the aforementioned inorganic material.

Although the method of manufacturing the release film of FIG. 2 has been specifically described in FIGS. 5A to 5D and 6A to 6C, this is exemplary and may be variously modified in some cases.

Hereinafter, the manufacturing process of the polyurethane layer which may be applied to the manufacturing method of the release film for a semiconductor package according to embodiments of the present invention will be described in more detail.

The number average molecular weight (a or weight average molecular weight) of the polyurethane resin used in the embodiment of the present invention may be about 50,000 to 500,000. Urethane (polyurethane) may be obtained by reaction of polyol and isocyanate, and may also be manufactured by controlling the reaction rate and molecular weight using a catalyst.

As the polyol, one or a mixture of two or more products having a molecular weight of about 500 to 7,000 may be used as a raw material. As the ether-based polyol, polypropylene glycol, modified polypropylene glycol, and polytetramethylene glycol (PTMG) may be used. As the polyester-based polyol, polyethylene glycol having a molecular weight in the range of about 500 to 7,000, polycarbonate-based polycondensation-based adipate-based polyester polyol, and ring-opening polymerization-based lactone-based polyol may be used. In addition, one or two or more of polybutadiene glycol and acryl-based polyol may be mixed and used. However, the above materials are exemplary, and the present application is not limited thereto.

As the isocyanate material, various diisocyanate-based materials may be used. For example, PPDI may be used as p-phenylene diisocyanate with a molecular weight of 160.1. TDI including isomer of toluene-diisocyanate may be used as toluene-diisocyanate with a molecular weight of 174.2. NDI may be used as 1,5-naphthalene diisocyanate with a molecular weight of 210.2. HDI may be used as 1,6-hexamethylene diisocyanate with a molecular weight of 168.2, MDI may be used as 4,4′-diphenylmethane diisocyanate with a molecular weight of 250.3. IPDI may be used as isoporon diisocyanate with a molecular weight of 222.3, and H12MDI may be used as cyclohexylmethane diisocyanate with a molecular weight of 262. However, the above materials are exemplary, and the present application is not limited thereto.

In addition, a chain extender material may be additionally used in addition to the polyol and isocyanate. The chain extender may serve to increase the molecular weight of the polyurethane and impart various functionalities. One to two or more of the chain extenders may be mixed and used. As the chain extender, ethylene glycol-based material, propylene glycol-based material, butadiene glycol-based material, polyhydric alcohol including silicone, polyhydric alcohol including fluorine, etc. may be used. However, the above materials are exemplary, and the present application is not limited thereto.

As the catalyst, various organic tin-based materials and organic bismuth-based materials may be used. The organotin-based material (an organotin-based compound) may include, for example, dibutyltin dilaurate, stannous octoate, dibutyltin diacetate, dibutyltin dimercaptide, and the like. Here, dibutyltin dilaurate is (CH₃CH₂CH₂CH₂)₂Sn[CH₃(CH₂)₁₀COO]₂, stannous octoate is Sn[C₇H₁₅COO]₂, dibutyltin diacetate is (CH₃CH₂CH₂CH₂)₂Sn[CH₃COO]₂, dibutyltin dimercaptide is (CH₃CH₂CH₂CH₂)₂Sn[SC₁₂H₂₅]. The organic bismuth-based material (an organic bismuth-based compound) may have various molecular weights, and may include, for example, a carboxylate-based catalyst material containing bismuth. Here, the carboxylate-based catalyst material may contain about 9% to about 45% of bismuth. However, the above materials are exemplary, and the present application is not limited thereto.

As a solvent for making a polyurethane resin solution, for example, various acetone solvents and etc. including DMF (dimethylformamide), DEF (diethylformamide), DMSO (dimethylsulfoxaide), DMAC (dimethylacetamide), toluene, ethyl acetate (EA), methyl ethyl ketone may be used. However, the above materials are exemplary, and the present application is not limited thereto.

After preparing a resin solution for preparing polyurethane in which the polyol, isocyanate, solvent, etc. are mixed, a polymer cured product having various crosslinking densities may be formed by reaction using a melamine-based curing agent, its catalyst, and an isocyanate-based curing agent polymerized with various molecular weights. In this case, a curing method using heat may be applied.

The composition of the curable polyurethane which may be applied to an embodiment of the present invention will be described as follows.

As for the polyurethane composition, polyol such as a polyester-based polyol (e.g., molecular weight 500 to 7,000), polyether-based polyol (e.g., molecular weight 200 to 3,000) or polycarbonate-based polyol (e.g., molecular weight 500 to 8,000) may be applied as a first material for the urethane reactioned, and an isocyanate-based material may be applied as a second material for the urethane reaction. As the isocyanate-based material, various isocyanate types containing a yellowing benzene-ring, and various isocyanates including hexamethylene-based, isophorone-based and cyclohexylmethane-based which are non-yellowing types may be used. In addition, a chain extender may be additionally used to increase the molecular weight of the polyurethane. As the chain extender, ethylene glycol-based materials, propylene glycol-based materials, butadiene glycol-based materials, polyhydric alcohols including silicone, polyhydric alcohols including fluorine, etc. may be used, and it is possible to increase the molecular weight of the polyurethane by allowing the chain extender to be involved in a urethane reaction.

As other additives, a leveling agent, an antifoaming agent, a curing agent, and the like may be additionally used. As the leveling agent, a modified polyether-based leveling agent including a silicone-based, fluorine-based or non-silicone-based leveling agent may be used, and the leveling agent may be used in a mixture of about 0.1 wt % to 5 wt %. The antifoaming agent is for a defoaming function, and for example, a silicone-based or non-silicone-based antifoaming agent may be used. The antifoaming agent may be used in a mixture of about 0.1 wt % to 5 wt %. In addition, as a curing agent for the curing reaction of the prepared polyurethane, a melamine-based curing agent and an isocyanate-based curing agent polymerized with several molecules may be used. In addition, the curing reaction may be accelerated in the presence of an acid catalyst.

In embodiments of the present invention, the formation of the polyurethane layer, the formation of the release layer, the formation of the antistatic layer, etc. may be performed by using a roll-to-roll process. In this case, the formation of the polyurethane layer, the formation of the release layer, the formation of the antistatic layer, etc. may be performed by any one of a micro-gravure coater, a direct gravure coater, a comma coater, and a slot die coater.

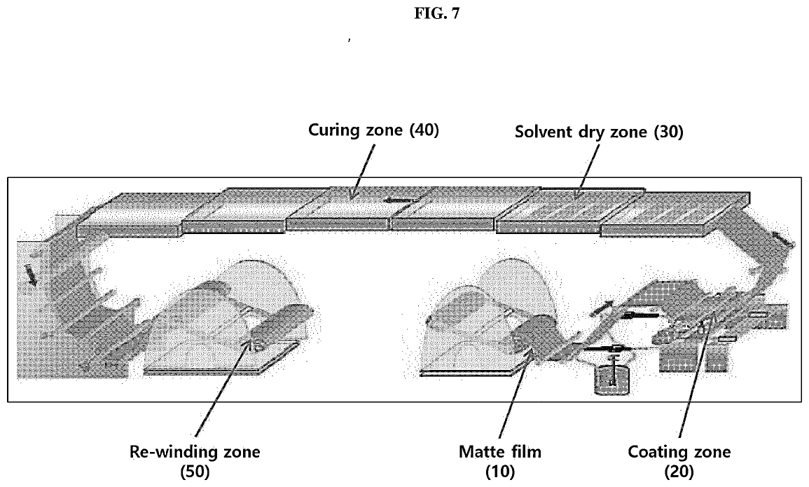

FIG. 7 is a diagram for explaining an apparatus applicable to a method of manufacturing a release film for a semiconductor package according to an embodiment of the present invention and a manufacturing process using the same.

Referring to FIG. 7, an apparatus applicable to the method for manufacturing a release film according to an embodiment of the present invention may be a coating apparatus using a roll-to-roll process. For example, the device may include a portion to which a carrier film 10 wound in the form of a roll is mounted, and it may be configured so that the carrier film 10 is transported while pulling one end of the carrier film 10. The carrier film 10 may be, for example, a matte film, but may be a film other than the matte film. The apparatus may include a coating zone 20 for applying a solution for forming a polymer on the carrier film 10 to be transported, a dry zone 30 for removing (drying) a solvent from the applied solution for forming a polymer (a polymer-forming film), and a dry zone 30 and a curing zone 40 for curing the applied solution for forming a polymer (a polymer-forming film) may be included. Curing in the curing zone 40 may include a curing process using heat or a curing process using ultraviolet (UV) light, or both of a curing process using heat or a curing process using ultraviolet (UV) light. In addition, the apparatus may include a re-winding zone 50 for rewinding the carrier film 10 on which the coating operation is completed as a form of a roll.

The configuration of the apparatus shown in FIG. 7 is merely exemplary, and may be variously changed. As an example, in FIG. 7, the case of curing the film for forming the polymer in the apparatus has been illustrated and described, but the film for forming the polymer may be cured by drying the film member as a form of a roll, which has been rewound under a predetermined drying condition. This may be referred to as ‘cure hardening’ or ‘dry curing after winding’. The cure hardening, for example, may be performed at a temperature of about 50° C. drying conditions for 24 hours or more. However, this is exemplary, and drying conditions may be variously changed. The curing which may be applied when manufacturing the release film according to the embodiment of the present invention may include not only the curing method in the coating apparatus, but also the cure hardening (a dry curing after winding) method described above.

In addition, in embodiments of the present invention, a method for bonding two material layers to each other may include both of a method for forming a solution for forming the other material layer on one material layer according to a coating method, or a method in which two material layers are mutually bonded to each other.

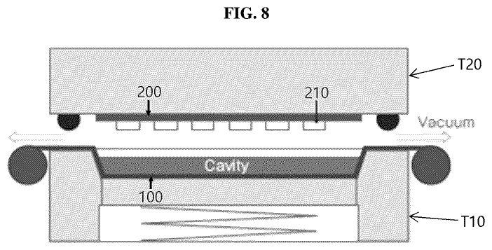

FIG. 8 is a diagram for explaining a molding process of a semiconductor package to which a release film for a semiconductor package according to an embodiment of the present invention is applied.

Referring to FIG. 8, a molding process of a semiconductor package may be performed by using the release film 100 according to an embodiment of the present invention. The molding apparatus may include a first molding tool T10 and a second molding tool T20 facing the first molding tool T10. The first molding tool T10 may be a lower molding tool, and the second molding tool T20 may be an upper molding tool.

A predetermined concave portion (a cavity region) may be provided in the first molding tool T10, and the release film 100 may be disposed to cover the concave portion. The release film 100 may be sucked so as to be in close contact with the surface of the concave portion by a vacuum adsorption method (i.e., a suction method). A substrate 200 having a plurality of semiconductor device portion 210 formed thereon may be disposed on a lower surface of the second molding tool T20. A molding material (e.g., EMC) (not shown) may be disposed on a portion of the release film 100 of the concave portion (a cavity region). A heating process for melting the molding material, and a vacuum compression process for attaching the molten molding material to the side of the semiconductor device portion 210 may be performed.

The release film 100 according to the embodiment of the present invention may have excellent mechanical properties which may withstand high temperature and high pressure conditions without rupture during the molding process of a semiconductor package, and also have excellent releasability (peelability). In particular, since the release film 100 includes a thermosetting material, it may have superior mechanical properties than a conventional release film based on a thermoplastic material. Therefore, the release film 100 according to the embodiment of the present invention may not rupture even under conditions of high temperature and high pressure. In addition, since the release film 100 according to the embodiment of the present invention has low permeability to the fume-gas generated during the molding process, the problems such as mold contamination and productivity decrease due to the fume-gas may be prevented.

In addition, the release film 100 according to the embodiment of the present invention may maintain excellent antistatic performance even during a high-temperature process. Even if a portion of the release film 100 is stretched during the semiconductor package molding process, the antistatic performance of the release film 100 may be maintained. Accordingly, it is possible to effectively prevent or suppress problems such as process defects, mold contamination, and damage/destruction of semiconductor devices due to the charging phenomenon during the semiconductor package process. Additionally, since the release film 100 according to an embodiment of the present invention has fine unevenness (refer to N10 and N20 in FIG. 1) on its lower surface and upper surface, it may have excellent releasability (peelability).

Therefore, when the release film 100 according to the embodiment of the present invention is used, the defect rate of the semiconductor package may be lowered, the productivity may be improved, and the characteristics of the manufactured package may be improved.

Table 1 below summarizes the results evaluating the resistance of the release film, resistance (surface resistance) change characteristics by elongation (elongation rate), and substrate adhesion strength of the release film, after manufacturing the release film having the structure shown in FIG. 1. At this time, the antistatic layers A10, A20 are formed by using a coating solution containing MWCNT as much as 1.5 wt %. In Table 1, ‘Wet thickness’ means the thickness before drying of the antistatic layer A10, A20 (that is, the thickness of the coated solution), and ‘coating surface resistance’ means the resistance (sheet resistance) (22/square) of the antistatic layer A10 or A20. As the resistance of the finished product, the resistance of the initial state and the resistance by elongation (10, 30, 50%) were measured. The notation of the resistance value follows the exponential notation. Here, the resistance is measured using a TREK 152-1 resistance meter.

TABLE 1

| Wet thickness (μm) | | 7~9 | 12~15 | 21~25 |
|---|---|---|---|---|
| Coating surface resistance (Ω/sq.) | | E8~E13 | E5~E6 | E4 |
| Resistance of final | initial state | E8~E13 | E5~E8 | E4~E6 |
| product | 10% | E8~E13 | E5~E8 | E4~E6 |
| Resistance change | 30% | E8~impossible | E6~E10 | E6~E10 |
| by elongation rate | | measurement | | |
| | 50% | impossible | E6~E11 | E6~E11 |
| | | measurement | | |

| | | | |
|---|---|---|---|
| Substrate adhesion | Good | Good | Slightly |
| | | | unstable |

Table 2 below summarizes the results evaluating the resistance of the release film, resistance (surface resistance) change characteristics by elongation (elongation rate), and substrate adhesion strength of the release film, after manufacturing the release film having the structure shown in FIG. 2. At this time, the antistatic layer A11 is formed by using a coating solution containing MWCNT as much as 1.5 wt %. In Table 2, ‘Wet thickness’ means the thickness before drying of the antistatic layer A11 (that is, the thickness of the coated solution), and ‘coating surface resistance’ means the resistance (sheet resistance) ((2/square) of the antistatic layer A11. As the resistance of the finished product, the resistance of the initial state and the resistance by elongation (10, 30, 50%) were measured. The notation of the resistance value follows the exponential notation. Here, the resistance is measured using a TREK 152-1 resistance meter.

TABLE 2

| Wet thickness (μm) | | 7~9 | 12~15 | 21~25 |
|---|---|---|---|---|
| Coating surface resistance (Ω/sq.) | | E8~E13 | E5~E6 | E4 |
| Resistance of final | initial state | E10~impossible | E8~E10 | E6~E8 |
| product | | measurement | | |
| Resistance change | 10% | E10~impossible | E8~E10 | E6~E8 |
| by elongation rate | | measurement | | |
| | 30% | E10~impossible | E8~E11 | E7~E9 |
| | | measurement | | |
| | 50% | E10~impossible | E9~E12 | E7~E12 |
| | | measurement | | |

| | | | |
|---|---|---|---|
| Substrate adhesion | Good | Good | Slightly |
| | | | unstable |

Referring to Tables 1 and 2 above, when the wet thickness is about 10 μm to 25 μm or about 10 μm to 20 μm in the embodiment of FIG. 1 and the embodiment of FIG. 2, it may be confirmed that the antistatic performance even at high elongation appears sufficiently (i.e., the resistance is about 10¹² Ω/sq. or less). Therefore, even if the release film according to the embodiment of the present invention is stretched by a high-temperature process, it is possible to maintain excellent antistatic performance. In addition, the release film was also generally excellent (good) adhesion to the substrate.

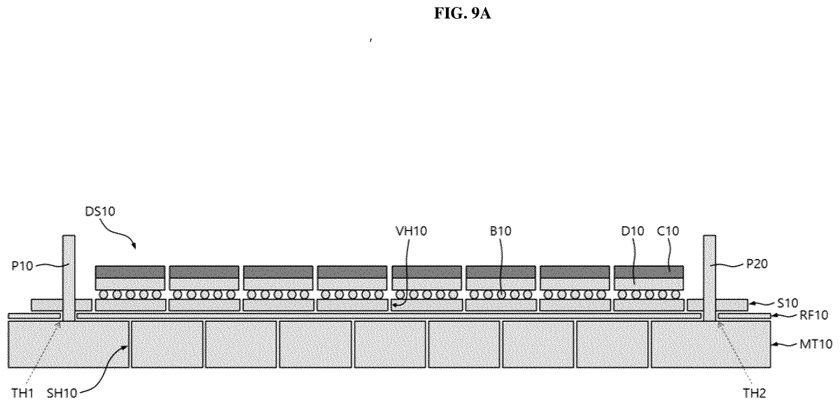

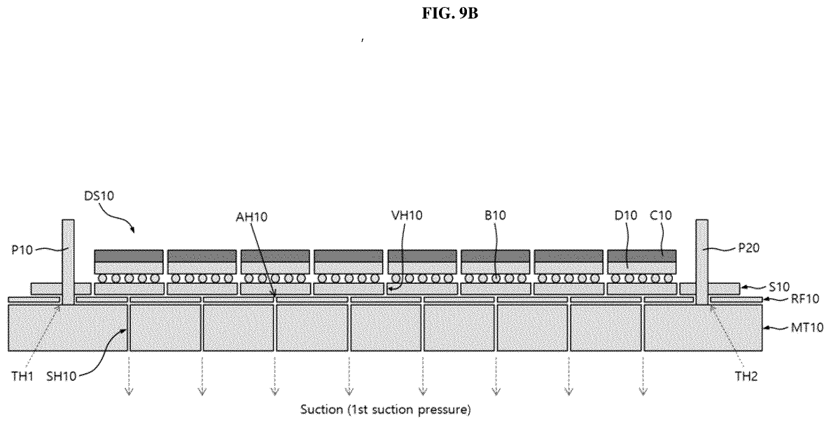

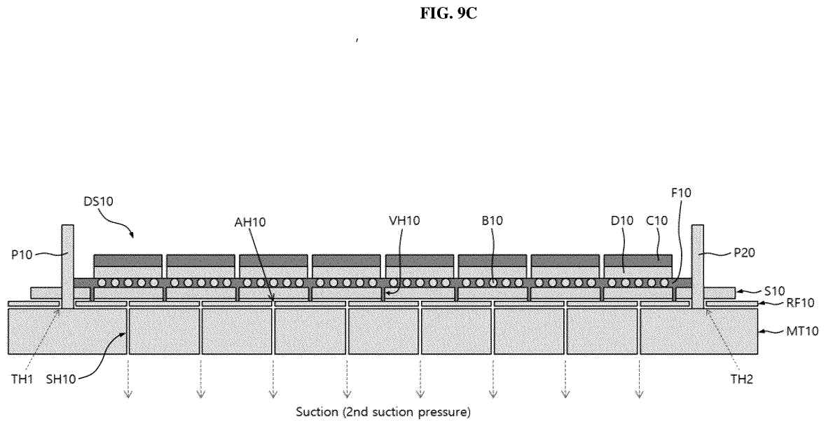

FIG. 9A to FIG. 9C are cross-sectional diagrams illustrating a method for forming an underfill according to an exemplary embodiment of the present invention.

Referring to FIG. 9A, a device structure DS10 including a circuit board S10 having at least one vent hole VH10, a plurality of semiconductor device portions D10 mounted on the circuit board S10, and a plurality of electrical connection members B10 disposed between the circuit board S10 and the plurality of semiconductor device portions D10 may be prepared.

The circuit board S10 may be a printed circuit board (PCB). For example, the circuit board S10 may be a flexible printed circuit board (FPCB). At least one vent hole VH10 passing through the circuit board S10 in its thickness direction may be formed. One or more vent holes VH10 may be formed, and may be formed in the central portion or edge region of the circuit board S10, or in an intermediate region between the central portion and the edge region. When the plurality of vent holes VH10 are formed, they may be formed to be relatively uniformly distributed over the entire region or substantially the entire region of the circuit board S10, or within a predetermined range. The formation positions and number of the plurality of vent holes VH10 illustrated in FIG. 9A are exemplary, and the present invention is not limited thereto, and various designs thereof may be made.

Each of the plurality of semiconductor device portions (units) D10 mounted or arranged on the circuit board S10 may be a semiconductor chip (i.e., a die). The plurality of semiconductor device portions D10 may be disposed to be spaced apart from each other at a predetermined interval. The plurality of semiconductor device portions D10 may be arranged to form a two-dimensional array. A plurality of electrical connection members B10 may be disposed between each of the semiconductor device portions D10 and the circuit board S10 to electrically connect them to each other. The electrical connection member B10 may be a solder bump. A plurality of first electrode pads may be formed on a lower surface of each semiconductor device portion D10, and a plurality of second electrode pads may be formed on an upper surface of the circuit board S10. The plurality of electrical connection members B10 may be disposed to interconnect the plurality of first electrode pads and the plurality of second electrode pads.

An upper molding layer C10 may be further formed on each semiconductor device portion D10. In other words, the device structure DS10 may further include a plurality of upper molding layers C10 formed on the plurality of semiconductor device portions D10. The upper molding layer C10 may be a kind of protective layer, and may be formed by, for example, a molding material such as an epoxy molding compound (EMC). Here, the case in which the upper molding layer C10 is individually formed on each semiconductor device portion D10 is illustrated, but in some cases, one molding layer (an upper molding layer) may be formed to completely cover the upper surfaces of the plurality of semiconductor device portions D10.

According to an embodiment of the present invention, after a first mold member MT10 having a plurality of suction holes SH10 is prepared, a first release film RF10 may be disposed on the first mold member MT10, and the device structure DS10 to be subjected to an underfill process may be disposed on the first release film RF10.

The first mold member MT10 may be referred to as a first molding tool member (an apparatus unit). The first mold member MT10 may be a mold member. For example, the first mold member MT10 may be a lower mold. The plurality of suction holes SH10 may be formed in the first mold member MT10. The plurality of suction holes SH10 may be arranged at a predetermined distance from each other in a regular or patterned manner. The plurality of suction holes SH10 may be formed to pass through the first mold member MT10 in the thickness direction, but in some cases, they may be formed so as to be bent and extended from the upper surface portion of the first mold member MT10 toward the side surface without penetrating in the thickness direction. The plurality of suction holes SH10 may be horizontally spaced apart from the vent hole VH10 so as not to overlap the vent hole VH10 of the circuit board S10. At least an upper end of the suction hole SH10 may be spaced apart from the vent hole VH10 in a horizontal direction so as not to overlap the vent hole VH10. The formation positions and number of the plurality of suction holes SH10 illustrated in FIG. 9A are merely exemplary and may be variously changed within the scope of the present invention.

In an embodiment, the first release film RF10 may be a thermosetting polymer film, as described above with reference to FIGS. 1 to 8. For example, the first release film RF10 may be a thermosetting polyurethane-based polymer film. In an embodiment, the first release film RF10 may be a thermosetting polyurethane film. The thermosetting polyurethane film may be formed by a polyurethane resin. In connection with the polyurethane resin, reference may be made to the disclosure regarding the polyurethane resin disclosed with reference to FIG. 1. As other additives, a leveling agent, an antifoaming agent, a curing agent, and the like may be further used.

The first release film RF10 may be a thermosetting polyurethane film formed by the above-mentioned thermosetting polyurethane resin. The content of the thermosetting polyurethane in the first release film RF10 may be about 80 wt % to 100 wt %. However, in some cases, the first release film RF10 may include a part (a small amount) of other polymer materials or other additives in addition to the thermosetting polyurethane. Also, in some cases, the first release film RF10 may be formed by other thermosetting polymer other than the thermosetting polyurethane-based polymer.

The first release film RF10 may have a thickness in a range of about 15 μm to about 60 μm. Under this thickness condition, the first release film RF10 may exhibit excellent mechanical properties which simplifies the process for forming a vent hole through rupture by a suction pressure, which will be described later in the underfill process according to the present embodiment. However, since the rupture process may be induced by weakening the strength of the first release film RF10 or increasing the suction pressure to be described later, in this case, the thickness of the first release film RF may be further increased. The first release film RF10 may be a film having releasability on both surfaces (a lower surface and an upper surface), and may be a film having fine unevenness forming surface roughness for improving releasability on at least one surface of the both surfaces. The formation of the fine unevenness may be optional.

The device structure DS10 may be disposed on the first release film RF10. In this case, the device structure DS10 may be disposed such that the circuit board S10 may face the first release film RF10. The lower surface of the first release film RF10 may be in contact with the upper surface of the first mold member MT10, and the lower end of the device structure DS10, that is, the lower end of the circuit board S10, may be in contact with the upper surface of the first release film RF10. Although not shown in FIG. 9A, a plurality of conductive members for contacting or mounting an external circuit such as a plurality of solder balls may be further formed on the lower surface of the circuit board S10. In this case, the plurality of the conductive members may be in contact with the upper surface of the first release film RF10, and the lower surface of the circuit board S10 may be slightly spaced apart from the upper surface of the first release film RF10.

According to an embodiment of the present invention, the first mold member MT10 may further include a first support pin portion P10 disposed in a first edge region (a first edge or a region adjacent thereto), and a second edge region (a second edge or a region adjacent thereto). In addition, the first release film RF10 may include a first through hole TH1 formed at a position corresponding to the first support pin portion P10, and a second through hole TH2 formed at a position corresponding to the second support pin portion P20. In the step for disposing the first release film RF10 on the first mold member MT10, the first support pin portion P10 may be inserted into the first through hole TH1, and the second support pin portion P20 may be inserted into the second through hole TH2. As described above, by inserting the first and second support pin portions P10 and P20 into the first and second through holes TH1 and TH2, respectively, it may be easy to align the first release film RF10 on the first mold member MT10 and to fix the position thereof. On the other hand, the arrangement, direction, and distance relationship between the first and second support pin portions P10 and P20 and the circuit board S10 shown in FIG. 9A may be determined in consideration of various process requirements such as flatness, alignment, and a fixing force of the release film RF10 required in the underfill process, and may be variously changed and implemented within the scope of the present invention.

Referring to FIG. 9B, a plurality of ventilation holes AH10 may be formed in the first release film RF10 by applying a first suction pressure to the plurality of suction holes SH10. The plurality of ventilation holes AH10 may be formed so that they may penetrate through the thickness direction of the first release film RF10 while a corresponding portion of the first release film RF10 facing each suction hole SH10 is being ruptured by the first suction pressure. Accordingly, the plurality of ventilation holes AH10 may be formed at positions corresponding to the plurality of suction holes SH10. More specifically, the plurality of ventilation holes AH10 may be formed at positions corresponding to upper ends of the plurality of suction holes SH10. As such, the plurality of ventilation holes AH10 may be formed by a suction process for applying the first suction pressure to the plurality of suction holes SH10. The first suction pressure may be a kind of vacuum pressure or negative pressure. In the present specification, the process for forming the plurality of ventilation holes AH10 in this way is referred to as a drilling process.

The first suction pressure for forming the plurality of ventilation holes AH10 may be, for example, in a range of about 20 KPa to about 90 KPa. In addition, in the step for forming the plurality of ventilation holes AH10, a temperature of the first mold member MT10 may be in a range of about 50° C. to about 250° C. When the suction pressure (i.e., the first suction pressure) condition and temperature condition are satisfied, the plurality of ventilation holes AH10 may be more easily formed by the drilling process, and a subsequent underfill process may also be easily performed by the ventilation hole AH10 aligned in the respective suction holes SH10.

As the first mold member MT10 is heated to the above-described temperature range, the device structure DS10 may also be heated. In this case, due to the difference in the coefficient of thermal expansion between the circuit board S10, and the semiconductor device portion D10 and the upper molding layer C10 of the device structure DS10, the device structure DS10 may be deformed as a convex shape in a downward direction (that is, in a U-shape). However, according to the embodiment of the present invention, when the plurality of ventilation holes AH10 are formed by using the first suction pressure, as the plurality of ventilation holes AH10 are formed, the device structure DS10 positioned above them may be strongly adsorbed and may be pulled downward by a strong instantaneous vacuum pressure through the plurality of ventilation holes AH10. Therefore, even if the device structure DS10 is deformed to be convex downwardly (i.e., U-shape) due to the heating, a plurality of ventilation holes AH10 are formed and a strong vacuum pressure is applied to the device structure DS10. Accordingly, the device structure DS10 may be closely adhered (adsorbed) toward the first mold member MT10 to form a flat structure, and may be fixed toward the first mold member MT10. In this regard, the effect of improving the workability of the underfill process may be obtained.

The plurality of ventilation (air-passing) holes AH10 may have a diameter of, for example, about 0.05 mm to about 8 mm. When the diameter is within this range, a subsequent underfill process using the plurality of ventilation holes AH10 may be more easily performed.

Referring to FIG. 9C, an underfill process in which gas existing above the first release film RF10 is sucked through the plurality of suction holes SH10 and the plurality of ventilation holes AH10 by applying a second suction pressure to the plurality of suction holes SH10, and an underfill material is filled between and around the plurality of electrical connection members B10 may be performed. As a result, an underfill material layer F10 may be formed without voids between and around the plurality of electrical connection members B10.

The underfill material may be a kind of resin. For example, the underfill material may include a material such as EMC. The underfill material may be supplied to an edge region of the device structure DS10 by using a predetermined dispenser. As the underfill material is supplied from the edge region of the device structure DS10 to the inside thereof, a capillary pressure may act, and the second suction pressure may be applied together with the capillary pressure, thereby performing an underfill process. The second suction pressure may be, for example, in the range of about 20 KPa to about 300 KPa. The second suction pressure may be equal to or substantially less than the first suction pressure described with reference to FIG. 9B. However, the present invention is not limited thereto, and the second suction pressure may be greater than the first suction pressure. In addition, in the step for forming the underfill material layer F10, the temperature of the first mold member MT10 may be controlled in a range of about 50° C. to about 250° C. When these conditions are satisfied, the underfill material layer F10 may be more easily formed.

In the step for forming the underfill material layer F10, a portion of the underfill material may pass through the vent hole VH10 of the circuit board S10, and contact the upper surface of the first release film RF10. At this time, since the vent hole VH10 and the ventilation hole AH10 do not overlap and are spaced apart in the horizontal direction, the underfill material passing through the vent hole VH10 may not be entered the ventilation hole AH10 or a suction hole SH10. In the embodiment of the present invention, by using the first release film RF10 in which the ventilation hole AH10 is formed, it is possible to fundamentally prevent the problem that the underfill material emitted through the vent hole VH10 contaminates the surface of the first mold member MT10 (i.e., the lower mold). Therefore, after performing one underfill process, the next underfill process may be performed without a separate cleaning process for the surface of the first mold member MT10 (i.e., the lower mold). Accordingly, workability and efficiency of the underfill process may be greatly improved.

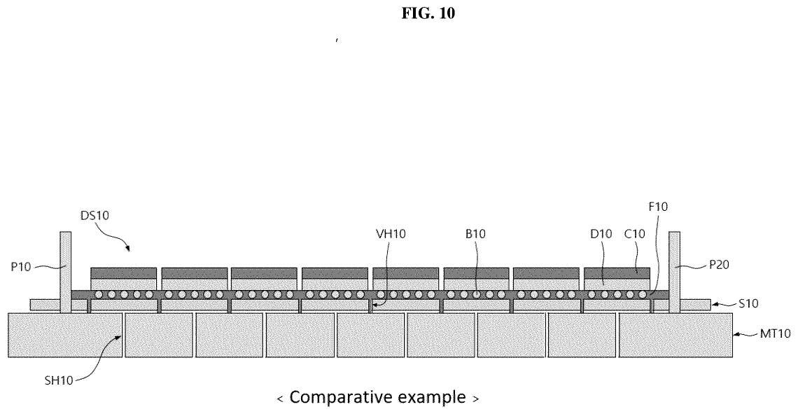

FIG. 10 is a cross-sectional diagram for explaining a problem of a method for forming an underfill according to a comparative example.

Referring to FIG. 10, when an underfill process is performed by directly disposing the device structure DS10 on the first mold member MT10 without the first release film RF10 described with reference to FIGS. 9A to 9C, the underfill material discharged through the vent hole VH10 may come into contact with the surface of the first mold member MT10 to contaminate the first mold member MT10. In this case, it is necessary to clean the surface of the first mold member MT10 every time the underfill process is performed. Accordingly, workability and process efficiency may be greatly reduced.

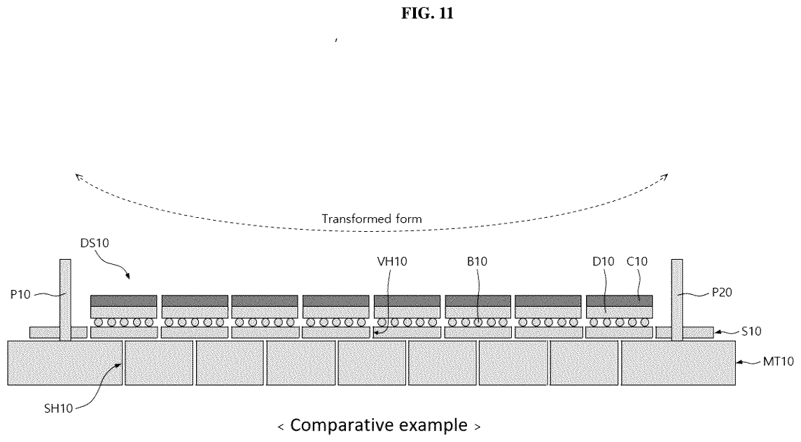

FIG. 11 is a cross-sectional diagram for explaining a problem of an underfill forming method according to a comparative example.

Referring to FIG. 11, when an underfill process is performed by directly disposing the device structure DS10 on the first mold member MT10 without the first release film RF10 described with reference to FIGS. 9A to 9C, if the device structure DS10 is loaded on the first mold member MT10 heated to a predetermined temperature, a problem in which the device structure DS10 is deformed to be convex downwardly (i.e., a U-shape) may occur due to the difference of the coefficient of thermal expansion among the circuit board S10, the semiconductor device portion D10 and the upper molding layer C10. Here, the shape of the deformation may be similar to the dotted line shown in an upper part of FIG. 11. In this way, under a state in which the device structure DS10 is deformed to be convex downwardly (i.e., a U-shape), even when a suction pressure is applied through the suction hole SH10, the edge portion of the device structure DS10 may not adhered well to the member MT10. Accordingly, it is necessary for an operator to forcibly deform a portion of the device structure DS10 to adhere to the first mold member MT10 during the suction process. Because of this reason, workability of the underfill process may be deteriorated.

However, according to the embodiment of the present invention, as described with reference to FIGS. 9A to 9C, the problems of the comparative examples shown in FIGS. 10 and 11 may be fundamentally or effectively solved. Accordingly, it is possible to obtain the effect that the workability and process efficiency of the underfill process are significantly improved.

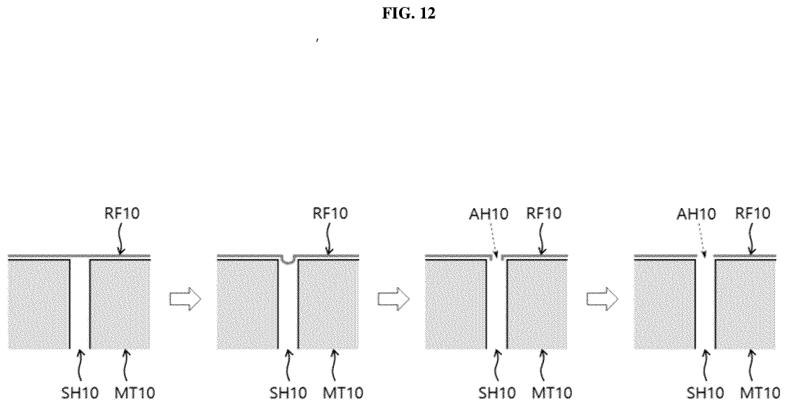

FIG. 12 is a schematic diagram for explaining a process of forming a ventilation hole in a release film in a method for forming an underfill according to an embodiment of the present invention.

Referring to FIG. 12, when the first release film RF10 is disposed on the first mold member MT10 having the suction hole SH10 and suction pressure is applied through the suction hole SH10, as a portion of the first release film RF10 facing the suction hole SH10 is tensilely deformed like a balloon and finally ruptured along the suction hole SH10, thereby forming a ventilation hole AH10 in the first release film RF10. At this time, the first release film RF10 may be a thermosetting polymer film. In this case, since the first release film RF10 has somewhat hard physical properties due to the characteristics of the thermosetting polymer film, the ventilation hole AH10 may be formed as it ruptures while resisting the suction pressure. If the portion corresponding to the suction hole SH10 in the first release film RF10 is stressed by the suction pressure and the ventilation hole AH10 is formed, the stress is relieved, and accordingly, a shape of the ventilation hole AH10 may be slightly adjusted. As a result, the ventilation hole AH10 as shown in the rightmost diagram of FIG. 12 may be formed. Accordingly, in the first release film RF10, the peripheral portion of the ventilation hole AH10 may not be introduced, or hardly be introduced into the suction hole SH10.

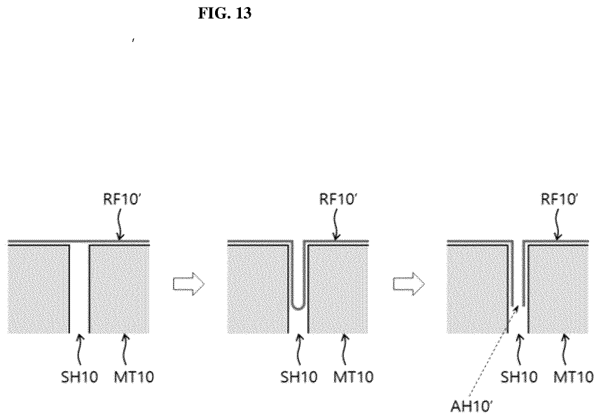

FIG. 13 is a schematic diagram for explaining a process of forming a vent hole in a release film in an underfill forming method according to a comparative example.

Referring to FIG. 13, a ventilation hole AH10′ may be formed in the release film RF10′ by disposing a release film RF10′ on the first mold member MT10 having a suction hole SH10, and applying suction pressure through the suction hole SH10. In this case, the release film RF10′ may be a thermoplastic polymer film. In this case, the release film RF10′ may be stretched to penetrate relatively deeply into the suction hole SH10 by the heating temperature and suction pressure, and the ventilation hole AH10′ may be formed as the lower end of the stretched portion is ruptured. Due to the characteristics of the thermoplastic polymer film, even after the ventilation hole AH10′ is formed, the portion extending (penetrating) into the suction hole SH10 in the release film RF10′ may maintain its state. Accordingly, in this case, there is a possibility that the suction hole SH10 may be blocked due to the release film RF10′. Therefore, it may be more preferable to use the above-described thermosetting polymer film instead of the thermoplastic polymer film.

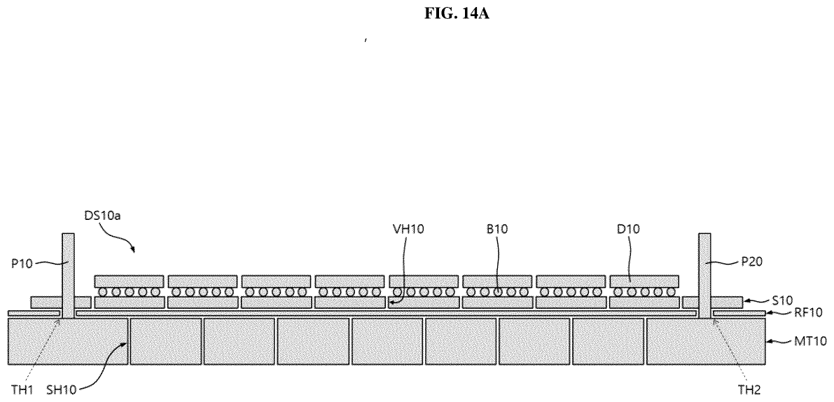

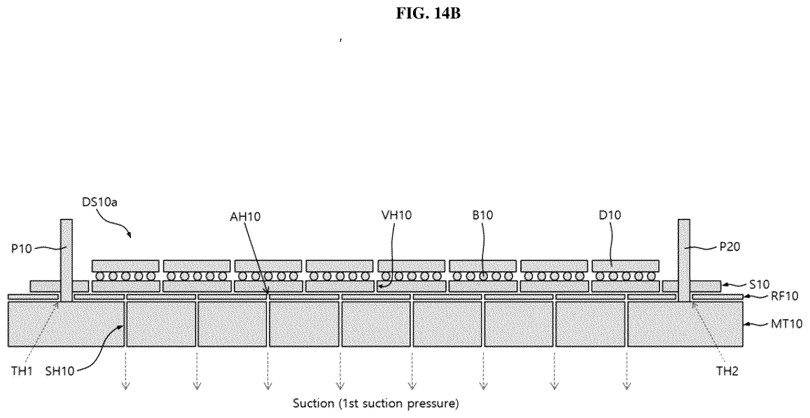

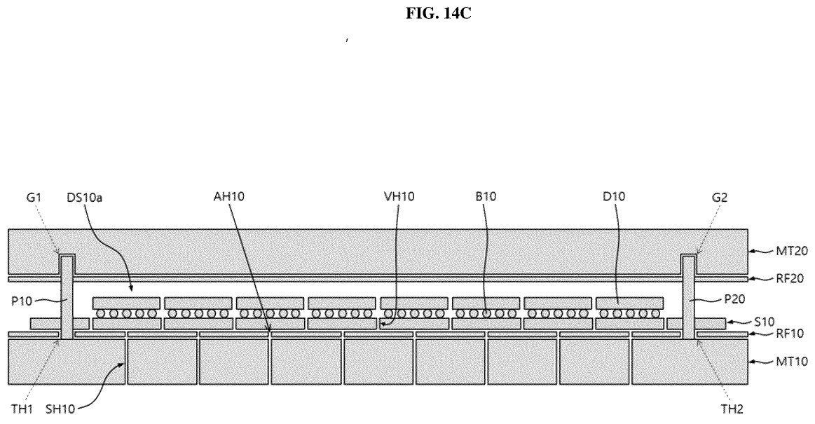

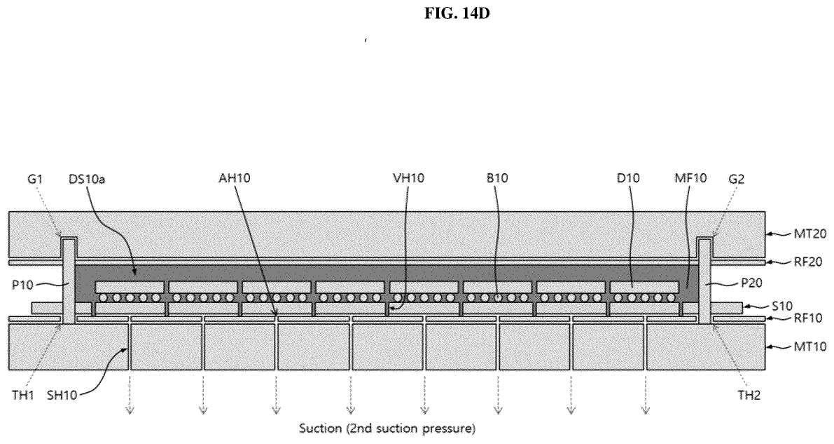

FIG. 14A to FIG. 14D are cross-sectional diagrams for explaining a method of forming an underfill according to another embodiment of the present invention.

Referring to FIG. 14A, a device structure DS10a including a circuit board S10 having at least one vent hole VH10, a plurality of semiconductor device portions D10 mounted on the circuit board S10, and a plurality of electrical connection members B10 between the circuit board S10 and a plurality of semiconductor devices may be prepared. In this case, the upper molding layer (C10 of FIG. 9A) as shown in FIG. 9A may not be provided on each semiconductor device portion D10. After preparing a first mold member MT10 having the plurality of suction holes SH10, a first release film RF10 may be disposed on the first mold member MT10, and the device structure DS10a may be disposed on the first release film RF10. The first release film RF10 may be a thermosetting polymer film. For example, the first release film RF10 may be a thermosetting polyurethane-based polymer film. The structure of FIG. 14A may be the same as or substantially the same as that of FIG. 9A except a fact that the upper molding layer (C10 of FIG. 9A) is not provided on the semiconductor device portion D10. Accordingly, the features described in FIG. 9A may be directly applied to FIG. 14A as well.

Referring to FIG. 14B, a plurality of ventilation holes AH10 may be formed in the first release film RF10 by applying a first suction pressure to the plurality of suction holes SH10. The process of FIG. 14B may be the same as or substantially the same as the process described with reference to FIG. 9B. Accordingly, the process conditions and characteristics described in FIG. 9B may be directly applied to FIG. 14B as well.

As illustrated in FIG. 14B, when the plurality of ventilation holes AH10 are formed by using the first suction pressure, the plurality of ventilation holes AH10 are formed, and as a result, it is possible to strongly adsorb the device structure DS10a above it and pull it downwardly due to instantaneous strong vacuum pressure through the plurality of ventilation holes AH10. Therefore, even if the device structure DS10a is deformed to be convex downwardly (i.e., U-shape) due to the heating, as a plurality of ventilation holes AH10 are formed and a strong vacuum pressure is applied to the device structure DS10a, the device structure DS10a may be fixedly adhered to (adsorbed) toward the first mold member MT10 while forming a flat structure. In this regard, the effect of improving the workability of the underfill process may be obtained.

Referring to FIG. 14C, a second mold member MT20 facing the first mold member MT10 may be disposed on the device structure DS10a. In this case, a second release film RF20 may be interposed between the second mold member MT20 and the device structure DS10a. The second mold member MT20 may be referred to as a second molding tool member (an apparatus unit). The second mold member MT20 may be a mold member, and may be referred to as an upper mold. The second release film RF20 may be the same film as the first release film RF10, but may be a different film.

A first insertion groove G1 into which the first support pin portion P10 is inserted and a second insertion groove G2 into which the second support pin portion P20 is inserted may be provided on a lower surface of the second mold member MT20. The second mold member MT20 may be disposed on the first mold member MT10 so that the first and second support pin portions P10 and P20 may be inserted into the first and second insertion grooves G1 and G2, respectively. However, the coupling relationship between the first mold member MT10 and the second mold member MT20 as illustrated herein is merely exemplary, and may be variously changed. Also, the arrangement relationship between the first and second support pin portions P10 and P20 and the second release film RF20 is exemplary and may be variously changed.

Although not shown in FIG. 14C, the first suction pressure described with reference to FIG. 14B may be continuously applied to the plurality of suction holes SH10 even in the step of FIG. 14C. That is, the first suction pressure described with reference to FIG. 14B may be continuously applied to the plurality of suction holes SH10 even in the step of FIG. 14C.

Referring to FIG. 14D, while gas above the first release film RF10 is being sucked through the plurality of suction holes SH10 and the plurality of ventilation holes AH10 by applying a second suction pressure to the plurality of suction holes SH10, an underfill process for filling an underfill material between and around the plurality of electrical connection members B10 may be performed. In this case, the underfill process may be a molded underfill (MUF) process. That is, while filling the underfill material between and around the plurality of electrical connection members B10, the upper surface of the plurality of semiconductor device portions D10 and the surrounding area may be molded with the underfill material. As a result, the MUF material layer MF10 may be formed on and around the upper surfaces of the plurality of semiconductor device portions D10 and peripheral regions thereof, and between and around the plurality of electrical connection members B10. The MUF material layer MF10 may include an underfill material layer. The underfill material may include a material such as EMC, and may be injected between the first mold member MT10 and the second mold member MT20 through a predetermined method.

The second suction pressure may be, for example, in a range of about 20 KPa to 200 KPa. The second suction pressure may be equal to or substantially smaller than the first suction pressure described with reference to FIG. 14B. However, the present invention is not limited thereto, and the second suction pressure may be greater than the first suction pressure. In addition, in the step for forming the MUF material layer MF10, the temperature of the first mold member MT10 may be controlled in a range of about 50° C. to about 250° C. When these conditions are satisfied, the MUF material layer MF10 may be more easily formed.

In the step for forming the MUF material layer MF10, a portion of the underfill material may pass through the vent hole VH10 of the circuit board S10, and contact the upper surface of the first release film RF10. At this time, since the bend hole VH10 and the ventilation hole AH10 do not overlap and are spaced apart in the horizontal direction, the underfill material passing through the vent hole VH10 may not enter the ventilation hole AH10 or a suction hole SH10 below it. In the embodiment of the present invention, by using the first release film RF10 in which the ventilation hole AH10 is formed, it is possible to fundamentally prevent the problem that the underfill material emitted through the vent hole VH10 contaminates the surface of the first mold member MT10 (i.e., the lower mold). Therefore, after performing one underfill process, the next underfill process may be performed without a separate cleaning process for the surface of the first mold member MT10 (i.e., the lower mold). Accordingly, workability and efficiency of the underfill process may be greatly improved.

After performing the underfill process using the method of FIGS. 9A to 9C or the method of FIGS. 14A to 14D, and separating the underfilled device structure from the first mold member MT10 and the first release film RF10, a semiconductor package (i.e., a semiconductor package device) may be manufactured by dividing the underfilled device structure into a plurality of unit devices.

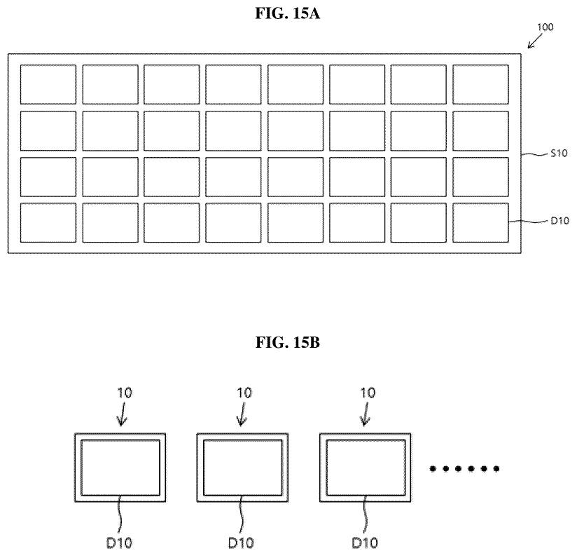

FIG. 15A and FIG. 15B are plan diagrams illustrating a process for dividing the underfilled device structure 100 into a plurality of unit devices 10 according to an embodiment of the present invention.

Referring to FIG. 15A, the underfilled device structure 100 may be formed by the method of FIGS. 9A to 9C or 14A to 14D. Here, reference numeral S10 denotes a circuit board, and D10 denotes a semiconductor device portion.

Referring to FIG. 15B, the underfilled device structure (100 of FIG. 15A) may be divided into a plurality of unit devices 10. Each unit device 10 may include a semiconductor device portion D10. The unit device 10 may be a packaged semiconductor device, that is, a semiconductor package device.

According to the embodiments of the present invention described above, process efficiency may be greatly improved by preventing the problem of contamination of the mold device (i.e., the mold) in the underfill process during a manufacturing process of the semiconductor package. In addition, according to embodiments of the present invention, it is possible to effectively solve the problem of deterioration of workability due to deformation of the substrate on the mold device (i.e., the mold) in the underfill process during the manufacturing process of the semiconductor package. According to embodiments, since the problem due to substrate deformation may be effectively solved while fundamentally preventing contamination of the mold apparatus (i.e., the mold) using a fairly simple method, a high process improvement effect may be obtained at low cost.

The techniques according to an embodiment of the present invention may be applied to various underfill processes as well as a molded underfill (MUF) process. That is, the techniques according to the embodiment may be applied to various underfill processes in which a vent hole (a resin through hole) is formed in the circuit board and the circuit board is brought into close contact with the lower mold through the suction hole of the lower mold. In addition, the techniques according to the embodiment may be applied to all kinds of semiconductor packages which may be manufactured through an underfill process, such as a ball grid array (BGA), a chip scale package (CSP), a flip chip, and a through silicon via (TSV).

In the present specification, preferred embodiments of the present invention have been disclosed, and although specific terms are used, these are only used in a general sense to easily describe the technical contents of the present invention and to help the understanding of the present invention, and are not used to limit the scope of the present invention. It will be apparent to those of ordinary skill in the art to which the present invention pertains that other modifications based on the technical spirit of the present invention may be implemented in addition to the embodiments disclosed herein. It will be appreciated to those of ordinary skill in the art that the methods for forming underfill and manufacturing methods of a semiconductor package using the same according to the embodiments described with reference to FIGS. 9A to 9C, 10, 14A to 14D, 15A and 15B may be variously substituted, changed and modified without departing from the spirit of the present invention. Therefore, the scope of the invention should not be determined by the described embodiments, but should be determined by the technical concepts described in the claims.

### EXPLANATION OF SYMBOLS FOR THE MAIN PARTS OF THE DRAWING

| | |
|---|---|
| A10, A11, A20: Antistatic layer | P10, P11, P21: Polyurethane layer |
| N10, N11: first fine unevenness | N20, N21: second fine unevenness |
| R10, R11: first release layer | R20, R21: second release layer |
| S10, S11: first surface | S20, S21: second surface |
| T10: first molding tool | T20: second molding tool |
| 10: carrier film | 20: coating zone |
| 30: drying zone | 40: curing zone |
| 50: rewinding zone | 100: release film |
| 200: substrate | 210: semiconductor device unit |
| AH10: Ventilation hole | B10: Electrical connection member |
| C10: upper molding layer | D10: semiconductor device portion |
| DS10, DS10a: device structure | F10: underfill material layer |
| G1, G2: insertion groove | MF10: MUF material layer |
| MT10: first mold member | MT20: second mold member |
| P10, P20: support pin unit | RF10: first release film |
| RF20: second release film | S10: circuit board |
| SH10: suction hole | TH1, TH2: through hole |
| VH10: vent hole | 10: unit element |
| 100: underfilled device structure | |

### INDUSTRIAL APPLICABILITY

Various embodiments of the present invention relate to semiconductor package manufacturing technology, and more particularly, may be implemented as a release film for a semiconductor package, a manufacturing method thereof, and a manufacturing method of a semiconductor package using the same.

1. A release film for a semiconductor package comprising:
an intermediate body layer including a structure in which at least one polyurethane layer and at least one antistatic layer are laminated;
a first release layer disposed on a lower surface of the intermediate body layer and having a first fine unevenness for releasability on a lower surface portion; and
a second release layer disposed on an upper surface of the intermediate body layer and having a second fine unevenness for releasability on an upper surface portion,
wherein the at least one polyurethane layer includes thermosetting polyurethane having a cross-linkage.

2. The release film of claim 1, wherein the antistatic layer includes a carbon nanotube (CNT).

3. The release film of claim 2, wherein a content of the CNT in the antistatic layer is 30 wt % to 90 wt %.

4. The release film of claim 2, wherein the CNT includes a multi-walled CNT (MWCNT).

5. The release film of claim 1,
wherein the intermediate body layer includes an intermediate polyurethane layer, a first antistatic layer disposed on a lower surface of the intermediate polyurethane layer, and a second antistatic layer disposed on an upper surface of the intermediate polyurethane layer,
wherein the intermediate polyurethane layer corresponds to the polyurethane layer, and the first and second antistatic layers correspond to the antistatic layer.

6. The release film of claim 1,
wherein the intermediate body layer includes a first polyurethane layer, a second polyurethane layer and an intermediate antistatic layer disposed between the first and second polyurethane layers,
wherein the first and second polyurethane layers correspond to the polyurethane layer, and the intermediate antistatic layer corresponds to the antistatic layer.

7. The release film of claim 1,
wherein the polyurethane layer has a thickness in a range of 10 μm to 70 μm,
wherein the antistatic layer has a thickness in a range of 0.1 μm to 2 μm,
wherein the release film has a thickness in a range of 30 μm to 140 μm.

8-9. (canceled)

10. The release film of claim 1, wherein at least one of the first and the second release layers have the same material composition as that of the polyurethane layer.

11. The release film of claim 1, wherein at least one of the first and the second release layers have a material composition different from that of the polyurethane layer.

12. The release film of claim 11,
wherein at least one of the first and second release layers includes an inorganic material,
when the first release layer includes the inorganic material, the first fine unevenness is formed on the lower surface portion of the first release layer by the inorganic material,
when the second release layer includes the inorganic material, the second fine unevenness is formed on the upper surface portion of the second release layer by the inorganic material.

13. A manufacturing method of a release film for a semiconductor package comprising:
preparing a polyurethane layer including thermosetting polyurethane having a cross-linkage;
forming a first release layer on any one of a lower surface and an upper surface of the polyurethane layer, and wherein the first release layer is formed while a first antistatic layer is being interposed between the polyurethane layer and the first release layer; and
forming a second release layer on the other one of the lower surface and the upper surface of the polyurethane layer, and wherein the second release layer is formed while a second antistatic layer is being interposed between the polyurethane layer and the second release layer,
wherein the first release layer has a first fine unevenness for releasability on an opposite surface to a surface in contact with the first antistatic layer, and the second release layer has a second fine unevenness for releasability on an opposite surface to a surface in contact with the second antistatic layer.

14. The manufacturing method of a release film of claim 13,
wherein the first and second antistatic layers are formed by a coating method using an antistatic coating solution,
wherein the antistatic coating solution contains 0.1 wt % to 2 wt % of carbon nanotube (CNT).

15. (canceled)

16. The manufacturing method of a release film of claim 14, wherein the first and second antistatic layers are formed by using a micro-gravure coater or a direct gravure coater.

17. The manufacturing method of a release film of claim 13, wherein at least one of the first and second release layers has the same material composition as that of the polyurethane layer.

18. The manufacturing method of a release film of claim 13, wherein at least one of the first and second release layers has a material composition different from that of the polyurethane layer.

19. A manufacturing method of a release film for a semiconductor package comprising:
preparing first and second polyurethane layers including thermosetting polyurethane having a cross-linkage; and
mutually bonding one surface of the first polyurethane layer and one surface of the second polyurethane layer and wherein the first and second polyurethane layers are mutually bonded while an antistatic layer is being interposed between the first and second polyurethane layers;
wherein a first release layer is provided on the other surface of the first polyurethane layer, a second release layer is provided on the other surface of the second polyurethane layer, the first release layer has a first fine unevenness for releasability on an opposite surface to a surface in contact with the first polyurethane layer, and the second release layer has a second fine unevenness for releasability on an opposite surface to a surface in contact with the second polyurethane layer.

20. The manufacturing method of a release film of claim 19,
wherein the antistatic layer is formed by a coating method by using an antistatic coating solution,
wherein the antistatic coating solution may contain 0.1 wt % to 2 wt % of carbon nanotube (CNT).

21. (canceled)

22. The manufacturing method of a release film of claim 20, wherein the antistatic layer is formed using a micro-gravure coater or a direct gravure coater.

23. The manufacturing method of a release film of claim 19, wherein at least one of the first and second release layers has the same material composition as that of the first and second polyurethane layers.

24. The manufacturing method of a release film of claim 19, wherein at least one of the first and second release layers has a material composition different from that of the first and second polyurethane layers.

25-51. (canceled)
